(19) United States
(12) Patent Application Publication
(10) Pub. No.: US 2010/0204826 A1
(43) Pub. Date: Aug. 12, 2010

(54) TRANSFER APPARATUS

(75) Inventors: Kazutoshi Sawado, Tokyo (JP); Yoshiaki Fujiwara, Ise-shi (JP); Masanao Murata, Ise-shi (JP); Takashi Yamaji, Ise-shi (JP); Naofumi Kirihata, Ichinomiya-shi (JP)

Correspondence Address: YOUNG & THOMPSON, 209 Madison Street, Suite 500, Alexandria, VA, 22314, US

(73) Assignee: MURATEC AUTOMATION CO., LTD., KYOTO-SHI (JP)

(21) Appl. No.: 12/705,545

(22) Filed: Feb. 12, 2010

(30) Foreign Application Priority Data
Feb. 10, 2009 (JP) 2009-028503
Aug. 6, 2009 (JP) 2009-183310

(51) Int. Cl. H01L 21/677

(52) U.S. Cl. 700/228; 414/222.07

(57) ABSTRACT

A transfer system includes: a first shelf blocking an original transfer path from a transfer position at which the transporting vehicle transfers the transported object to the port and which transfers the transported object with the transporting vehicle; a second shelf that puts the transported object; a displacing device which reciprocates the transported object with respect to the first shelf and the port in a first direction, toward and away from the processing apparatus, and reciprocates the transported object at a first direction position, away in the first direction by the transported object from the first shelf and the port, in a second direction crossing the first direction; and a communicating device receiving a first system signal indicating a transfer request from the transporting vehicle, which transmits a second system signal indicating a transfer permission to the transporting vehicle, which transmits the first system signal to the processing apparatus.

### BACKGROUND OF THE INVENTION

1. Field of the Invention

The present invention relates to a transfer apparatus for transferring a transported object, such as a container which accommodates or houses various substrates for manufacturing semiconductor devices, between a processing apparatus, such as a semiconductor manufacturing apparatus, and a transporting vehicle, such as a vehicle, which travels along a track. Here, the “transported object” in the present invention means a product, an intermediate product, a part, an article, a work, a partly-finished good, a good or the like (e.g. a semiconductor or LCD device), or means a box or container for containing such a product or the like (e.g, a container containing the semiconductor or LCD device), which has been transported or is to be transported by a transporting carriage. The load may be a carrier for containing an object to be carried such as a FOUP.

2. Description of the Related Art

As this kind of transfer apparatus, for example, such an apparatus is commercialized that is fixed to the outer frame of a processing apparatus or the exterior of an outer casing and that transfers a transported object, such as a container which is referred to as a FOUP (Front Opening Unified Pod), between the transfer apparatus and the processing apparatus or between the transfer apparatus and the transporting vehicle. Specifically, the transfer apparatus is equipped with two shelves, such as a port, for transferring the FOUP with the transporting vehicle on the top, and is equipped with six shelves, such as a buffer storage, for temporarily putting the FOUP below the port (e.g. refer to Japanese Patent No. 4182521).

Moreover, as the aforementioned transfer apparatus, such an apparatus has been suggested that is provided with a plurality of shelves, each of which can support the transported object, such as a wafer support pod; and a gripper, which can be displaced to any position in an X-Z plane including the plurality of shelves. Specifically, this system supplies the wafer support pod to the processing apparatus, such as a semiconductor process tool and a measurement tool (e.g. refer to Japanese Patent Kohyo (Japanese translation of PCT international application) No. 2001-509465).

However, the transfer apparatus described in Japanese Patent No. 4182521 and Japanese Patent Kohyo (Japanese translation of PCT international application) No. 2001-509465 is firmly fixed to the outer frame of the processing apparatus or the outer casing. In other words, once the transfer apparatus is fixed to the processing process, it takes a long time for an operation of canceling the fixation. Moreover, when the transfer apparatus is fixed to the processing apparatus, the transfer apparatus blocks the front of the processing apparatus (in particular, a wall portion in which the port for taking the transported object in and out exists). Thus, it is hard or impossible to perform operations associated with the repair, failure, and maintenance of the processing apparatus while the transfer apparatus remains fixed. In other words, in order to perform the operation associated with the repair or the like, there arises a time-consuming operation of detaching the transfer apparatus from the processing apparatus. Moreover, after that, when the transfer apparatus is fixed again to the processing apparatus, there also arises a new fixation operation between the two, which requires a certain degree of positioning accuracy. Moreover, with regard to the transfer apparatus, it is bulky in appearance to a non-negligible extent and its fixation position is limited, so that it will be a major hurdle when it is tried to save a space around the processing apparatus in a factory, which is technically problematic.

### SUMMARY OF THE INVENTION

It is therefore an object of the present invention to provide a transfer apparatus which can be easily fixed to a processing apparatus, with the entire apparatus miniaturized.

The above object of the present invention can be achieved by a transfer apparatus for transferring a transported object with a transporting vehicle, which travels along a track and which transports the transported object, and with a port which can take in and out the transported object or a processed object in a processing apparatus which performs a process on the processed object accommodated in the transported object, the transfer apparatus provided with: a first shelf which is disposed to block an original transfer path in the middle which is from a transfer position at which the transporting vehicle transfers the transported object to the port and which can transfer the transported object with the transporting vehicle; a second shelf which can at least temporarily put the transported object; and a displacing device which can reciprocate the transported object with respect to the first shelf and the port in a first direction, which is a direction coming close to and going away from the processing apparatus, and which can reciprocate the transported object at a first direction position, which is away in the first direction at least by the transported object from the first shelf and the port, in a second direction crossing the first direction.

The processing apparatus of the present invention is a semiconductor manufacturing apparatus, such as a process apparatus and an inspection apparatus, and it performs a predetermined process (e.g. an exposure process, film formation, heat treatment, or the like) on the transported object, such as a FOUP, and actually on the processed object, such as wafers accommodated in the transported object. When the process is performed, typically, the transported object to be processed is transported to the processing apparatus by the transporting vehicle, such as an OHT (Overhead Hoist Transport), which travels along the track laid on a ceiling in a factory, such as a semiconductor manufacturing factory, and it is transferred from the transporting vehicle or to the port which can transfer it to the transporting vehicle. After that, for example, the processed object accommodated in the transported object on the port is taken out of the transported object by the displacing device of the processing apparatus, and it is taken into and out of the processing apparatus. Incidentally, if the processing apparatus is provided with a buffer in a form of the processed object which is taken into or out of the processing apparatus as a processing target, it is not necessarily the processed object itself as described above, but it may be the transported object itself (i.e. the transported object which accommodates the processed object).

Here, for example, in semiconductor manufacturing, it is a challenge to improve the operating rate of the processing apparatus in order to ensure more production without expanding manufacturing facilities. For example, it is assumed that a waiting time for the transported object (i.e. the down time of the processing apparatus) between when the transported object on which the process has been completed is taken away from the port by a first transporting vehicle and when the transported object to be processed from now is brought to the port by a second transporting vehicle is several minutes. In contrast, the operating rate of the processing apparatus is 50% if it takes several minutes for the process in a first transported object. As described above, in order to improve the operating rate which reduces in accordance with the waiting time, it is requested to reduce the down time of the processing apparatus by quickly removing the transported object on which the process has been completed in the processing apparatus from the port and by quickly putting the transported object to be processed next onto the port (i.e. by quickly replacing the transported object on the port).

According to the transfer apparatus of the present invention, the transfer apparatus is a temporally-holding apparatus, such as a buffering apparatus for temporarily putting or holding the transported object on which the process is to be performed or has been performed by the processing apparatus. According to the transfer apparatus, for example, in the operation, firstly, the transportation and the process with respect to the first transported object are requested of three elements on the basis of a semiconductor manufacturing schedule by the controlling device in the manufacturing system for integrally controlling the transfer apparatus, the transporting vehicle, and the processing apparatus (hereinafter referred to as “three elements” as occasion demands). Then, the transporting vehicle which transports the first transported object is stopped at a position corresponding to the first shelf, and the first transported object is transferred from the transporting vehicle to the first shelf. Here, the “first shelf” means a shelf which is referred to as an “OHT port” and which has a put surface on which the transported object transferred from or to the transporting vehicle can be put. The first transported object transferred to the first shelf is transferred from the first shelf to the port by the displacing device, such as a robot arm which can hold the flange of a FOUP and a transfer mechanism which can support the transported object from below. After that, the processed object accommodated in the first transported object is displaced from the inside of the transported object on the port to the inside of the processing apparatus, for example, by an inner and outer displacing device in the processing apparatus. Then, the process is performed on the processed object within the processing apparatus. Then, the transportation and the process with respect to a second transported object to be processed next are requested of the three elements. Then, the transporting vehicle which transports the second transported object is stopped at the position corresponding to the first shelf, and the second transported object is transferred (i.e. brought) from the transporting vehicle to the first shelf. Then, the second transported object on the first shelf is transferred from the first shelf to the second shelf by the displacing device. Here, the “second shelf” means a shelf which is referred to as a “buffer” or a “buffer shelf” and which has a put surface on which either the first or second transported object can be temporarily put in order to replace the transported object on the port from the first transported object on which the process has been completed to the second transported object on the first shelf to be processed next. Then, if the process has been completed on the first processed object (actually, the processed object in the first transported object), the processed object is displaced by the inner and outer displacing device from the inside of the processing apparatus to the inside of the first transported object on the port. Then, the transportation (i.e. taking away) of the first transported object on which the process has been completed is requested of the transporting vehicle which is closest to the transfer apparatus or the processing apparatus, out of unloaded transporting vehicles which do not transport the transported object. After that, in parallel with that the first transported object on the port is transferred by the displacing device from the port to the first shelf (i.e. that the first transported object on which the process has been completed is taken away from the port), the transportation and the process (i.e. bringing in) with respect to a third transported object to be processed next to the second transported object are requested of the three elements. Then, the second transported object on the second shelf is transferred from the second shelf to the port, and the replacement of the transported object on the port is quickly performed. After that, by the transporting vehicle which is requested to transport the first transported object on which the process has been completed, the first transported object on the first shelf is transferred from the first shelf to the transporting vehicle (i.e. taken away). On the other hand, if the process has been completed on the second transported object on the port (actually, the processed object in the second transported object), the transportation (i.e. taking away) of the second transported object on which the process has been completed is requested of the transporting vehicle which is unloaded and which is closest to the transfer apparatus or the processing apparatus. As described above, by transferring the transported object to be processed from now to the first shelf in order and by using the second shelf to efficiently replace the transported object on the port on which the process has been completed by the transported object on the first shelf, it is possible to improve the operating rate of the processing apparatus.

As described above, the transfer apparatus of the present invention is provided only with: the one second shelf for replacing the transported object in the one port; and the first shelf for transferring the transported object with the transporting vehicle, as the shelf which can put or transfer the transported object. Thus, it is possible to make the transfer apparatus small and light. Moreover, in the situation that the transfer apparatus is miniaturized, the transfer apparatus can be easily fixed to the one port (or processing apparatus), and there is provided the displacing apparatus which can be displaced among the one port, the first shelf, and the second shelf. Thus, the connection may be unnecessary.

Moreover, according to the transfer apparatus of the present invention, with regard to the inner arrangement and the outer arrangement, firstly, the first shelf is disposed to block the original transfer path in the middle which is from the transfer position at which the transporting vehicle transfers the transported object, typically, the transfer position at which the transporting vehicle performs longitudinal transfer in the vertical direction, to the port. Thus, as viewed from the transporting vehicle side, it is possible to perform the transfer operation on the port if there is no transfer apparatus and to perform the transfer operation on the first shelf if there is the transfer apparatus, in almost the same manner. Moreover, the displacing device can reciprocate the transported object with respect to the first shelf and the port in the first direction (e.g. horizontal one direction), which is a direction coming close to and going away from the processing apparatus, and more specifically, an outer frame, outer casing surface, side surface, or side wall on which the port is provided in the processing apparatus. Moreover, the displacing device can reciprocate the transported object at the first direction position (e.g. horizontal direction position), which is away in the first direction at least by the transported object from the first shelf and the port, in the second direction (e.g. vertical direction). Thus, it is possible to include a path or space for displacing the transported object in the transfer apparatus, in an extremely small space. In particular, if such a condition is added that the second shelf which functions as the buffer does not block the path or space in the direction reciprocation of the transported object between the first shelf and the port, it is possible to approximately minimize the path or space for displacing the transported object in the transfer apparatus as described above. In other words, it is possible to reduce the width of the path or space for displacing the transported object in the transfer apparatus, within the width of the port. Thus, with respect to one processing apparatus provided with a plurality of ports, it is also possible to dispose the same number of transfer apparatuses as the number of ports in line along the track. In other words, it is also possible to make the outer width of the outer frame or outer casing or the like of the transfer apparatus, equal to, or less than or equal to the pitch of the ports. By this, it is also possible to select whether or not to use the transfer apparatus for each port, as occasion demands.

In one aspect of the transfer apparatus of the present invention, the second shelf is disposed at a position of the first direction position, which is not obstructive when the displacing device displaces the transported object in the first direction and the second direction between the first shelf and the port.

According to this aspect, the second shelf is disposed at the position of the first direction position (e.g. a position at which a distance in the horizontal direction from the outer wall on which the port is provided in the processing apparatus is fixed), which is not obstructive when the transported object is displaced in the first direction (e.g. horizontal direction) and the second direction (e.g. vertical direction) between the first shelf and the port. Specifically, for example, the second shelf is disposed near the lower limit in the movable range in the vertical direction of the displacing device, at the horizontal direction position located slightly below the port, which is close to the port disposed below the first shelf. Alternatively, the second shelf is disposed near the upper limit in the movable range in the vertical direction of the displacing device, at the horizontal direction position located slightly above the first shelf. Thus, it is possible to approximately minimize the path or space for displacing the transported object in the transfer apparatus while the second shelf which particularly functions as the buffer does not block the path or space in the direct displacement of the transported object between the first shelf and the port. Thus, it is possible to approximately minimize the outer shape of the outer frame or outer casing or the like of the transfer apparatus.

Alternatively, in another aspect of the transfer apparatus of the present invention, the second shelf is disposed between the first shelf and the port in the original transfer path.

According to this aspect, the second shelf is disposed between the first shelf and the port in the original transfer path, and the three parts of the first shelf, the second shelf, and the port are disposed in such a form that they are distant from each other. Therefore, it is possible to approximately minimize the path or space for displacing the transported object in the transfer apparatus while not blocking the path or space in the displacement of the transported object among the three parts at a second direction position. Thus, it is possible to approximately minimize the outer shape, such as the outer frame and outer casing, of the transfer apparatus.

In another aspect of the transfer apparatus of the present invention, the processing apparatus has a plurality of ports, and the transfer apparatus has a width which is less than or equal to an arrangement pitch of the ports in its outside dimension and is disposed such that the first direction matches a direction which is at right angles to a direction of arranging the ports.

According to this aspect, the transfer apparatus has the width which is less than or equal to the arrangement pitch of the ports in its outside dimension, and typically, the first direction matches the direction which is at right angles to the direction of arranging the ports, wherein the direction of arranging the ports is along the track. Thus, it is possible to place a plurality of transfer apparatuses correspondingly to the ports, in a one-to-one manner. Since the width of the transfer apparatus is small with respect to the width direction of the port, it is also possible to arrange the plurality of transfer apparatuses in accordance with the arrangement of the ports.

In another aspect of the transfer apparatus of the present invention, the first shelf can be bent or accommodated on a main body side of the transfer apparatus.

According to this aspect, if the transfer apparatus is removed for maintenance or the like or is installed, the first shelf is bent or accommodated on the main body side of the transfer apparatus. By this, it is only necessary to pull out or displace the transfer apparatus which is narrowed by the bent or accommodated portion, so that it is extremely useful in practice.

Incidentally, if the second shelf is disposed between the first shelf and the port in the original transfer path, it may be also constructed such that the second shelf can be bent or accommodated on a main body side of the transfer apparatus.

Specifically, the first shelf and/or the second shelf are fixed to one portion of a slide mechanism, and they are slide below the track or to the horizontal one direction position. For example, the first shelf and/or the second shelf are rotatably fixed to a hinge, and they are displaced to a put position horizontally disposed below the track, or an accommodation position vertically disposed in an accommodation device.

In another aspect of the transfer apparatus of the present invention, the transporting vehicle longitudinally transfers the transported object in a vertical direction, the first direction is a horizontal one direction which is perpendicular to the vertical direction, and the second direction is the vertical direction.

According to this aspect, the transporting vehicle can perform the longitudinal transfer on the port along the original transfer path which extends in the vertical direction if the transfer apparatus is not provided in the processing apparatus, and the transporting vehicle can also perform the longitudinal transfer on the first shelf along the original transfer path in the same manner even if the transfer apparatus is provided in the processing apparatus. Moreover, by the displacing device displacing the transported object put on the first shelf in the horizontal one direction and the vertical direction, it is possible to displace it to the second shelf or the port. Alternatively, by the displacing device displacing the transported object put on the port in the horizontal one direction and the vertical direction, it is possible to displace it to the second shelf or the first shelf.

In this aspect, the transporting vehicle is provided with, for example, a hoist mechanism which can hoist the transported object, and the hoist mechanism holds the transported object within the transporting vehicle in the transportation (i.e. including the travel in the transportation) and brings down or pulls up the transported object in the vertical direction with a transfer shelf, such as a stocker or the port, of the processing apparatus or the like, in the transfer. Here, the “longitudinal transfer” in the transporting vehicle means that the transported object is transferred by the displacement in the vertical direction. Typically, the port of the processing apparatus is placed in the vertical direction of the track. In this case, according to this aspect, the first shelf is disposed between the port and the transporting vehicle which is stopped at the transfer position, and the second shelf is disposed below the first shelf, specifically, between the first shelf and the port, or below the port.

In another aspect of the transfer apparatus of the present invention, the transfer apparatus has an outer shape which allows the transfer apparatus to be attached to the port, and the transfer apparatus is further provided with a positioning device for positioning the transfer apparatus with respect to the port.

According to this aspect, the main body of the transfer apparatus is, for example, an outer frame, outer casing, case, or frame. According to this aspect, the transfer apparatus is attached to the port such that there is the port in an area in the first direction (e.g. horizontal one direction) and the second direction (e.g. vertical direction) to which the displacing device can reach, in the operation. For the attachment, for example, the transfer apparatus main body has the outer shape which avoids the port and the transported object on the port. Moreover, the transfer apparatus has the outer shape which opens a portion adjacent to the transported object on the port in the transfer apparatus main body such that the displacing device can transfer the transported object with the port.

Moreover, according to this aspect, for example, it is possible to position the transfer apparatus by setting one portion of the transfer apparatus to the positioning device, such as a positioning block or pin, placed below the port or on the floor surface below the transfer apparatus. Incidentally, the positioning device may be provided not only on the floor surface but also on an inner wall or the like in a factory, such as a semiconductor manufacturing factory, rail, processing apparatus, or port.

In this aspect, the transfer apparatus may be further provided with a fixing device which fixes the transfer apparatus in a state that the transfer apparatus is positioned by the positioning and which can release the fixation.

By virtue of such construction, it is possible to fix the transfer apparatus by fixing one portion of the positioned transfer apparatus to the fixing device which is fixed on the floor surface, rail, or ceiling and which is made of a high-strength material.

In another aspect of the transfer apparatus of the present invention, it is further provided with a travelling device which enables the transfer apparatus to be displaced in the first direction.

According to this aspect, the transfer apparatus can be displaced by providing a plurality of travelling devices, such as a travel roller and a travel caterpillar, on the bottom surface of the transfer apparatus main body. In particular, in the attachment to the port, the transfer apparatus is displaced in the first direction, which is horizontal one direction, with respect to the port. In other words, the transfer apparatus can be arbitrarily attached or detached with respect to the port. Incidentally, the travelling device may be a transportation carriage which can support the transfer apparatus from below even if it is not provided for the transfer apparatus main body.

In another aspect of the transfer apparatus of the present invention, the displacing device has: a holding device for holding the transported object; a first displacing part capable of reciprocating the holding device in the first direction; and a second displacing part capable of reciprocating the holding device in the second direction.

According to this aspect, the displacing device holds the transported object by using the holding device, such as a gripper which can hold the upper part of the transported object and a transfer mechanism which can support the transported object from below, in the operation. Then, the displacing device which holds the transported object is displaced in the first direction (e.g. horizontal one direction) and the second direction (e.g. vertical direction) among the port, the first shelf, and the second shelf (i.e. the three element) by the first displacing device, which is, for example, a horizontal displacing device, driven by the power of an actuator, a motor, or the like, and the second displacing device, which is, for example, a vertical displacing device. As described above, it is possible to quickly displace the transported object onto an arbitrary put surface of the three elements, by simple biaxial operation performed by the two-direction displacing devices.

In another aspect of the transfer apparatus of the present invention, it is further provided with a controlling device for controlling the displacing device, if one transported object transferred from the transporting vehicle to the first shelf is displaced to the port, firstly to displace the one transported object from the first shelf to the second shelf, secondly to displace another transported object, which is put on the port, from the port to the first shelf while the one transported object is temporarily put on the second shelf, and thirdly to displace the one transported object from the second shelf to the port.

According to this aspect, if the one transported object is transferred from the transporting vehicle to the first shelf, the one transported object is firstly displaced to the second shelf by the displacing device, under the control of the controlling device including a controller or the like. Then, while the one transported object is temporarily put on the second shelf, the other transported object, on which the process has been completed by the processing apparatus and which is put on the port, is displaced to the first shelf by the displacing device. After that, the one transported object temporarily put on the second shelf is displaced to the port by the displacing device, and it is used for the subsequent process by the processing device.

As described above, it is possible to prioritize carrying out the other transported object on which the process has been completed to the first shelf, over carrying the one transported object into the port. By this, for example, it is possible to appropriately respond to the situation that the entire operation efficiency can be increased by rapidly transporting the transported object on which the process has been completed by using the transporting vehicle.

In another aspect of the transfer apparatus of the present invention, it is further provided with a controlling device for controlling the displacing device, if one transported object transferred from the transporting vehicle to the first shelf is displaced to the port, firstly to displace the one transported object to the port without temporarily putting the one transported object on the second shelf on which another transported object transferred to the second shelf is already put, and secondly to displace the other transported object from the second shelf to the first shelf.

According to this aspect, if the one transported object is transferred from the transporting vehicle to the first shelf, the one transported object is displaced directly to the port without being displaced to the second shelf, by the displacing device, under the control of the controlling device including a controller or the like. On the other hand, when the one transported object is displaced from the first shelf to the port, the other transported object is already put on the second shelf. Normally, the predetermined process is already performed on the other transported object by the processing apparatus. After that, the other transported object is displaced from the second shelf to the first shelf and is transported from the first shelf by the transporting vehicle which is closest and empty or the transporting vehicle which arrives next.

As described above, it is possible to carry out the other transported object on which the process has been completed to the first shelf after carrying the one transported object into the port. By this, for example, for example, it is possible to appropriately respond to the situation that the entire operation efficiency can be increased by rapidly transporting the unprocessed transported object to the processing apparatus.

Incidentally, the aforementioned two types of control in the two aspects can be also selectively performed according to circumstances. For example, any of the two types of control may be selected and performed, as occasion demands, in accordance with various situations, such as a processing standby situation and a transfer standby situation of the transported object on the port, a transfer standby situation and a transportation standby situation in the first shelf.

The above object of the present invention can be also achieved by a second transfer apparatus for transferring a transported object with a transporting vehicle, which travels along a track and which transports the transported object, and with a port which can take in and out the transported object or a processed object in a processing apparatus which performs a process on the processed object accommodated in the transported object, the transfer apparatus provided with: a first shelf which is disposed to block an original transfer path in the middle which is from a transfer position at which the transporting vehicle transfers the transported object to the port and which can transfer the transported object with the transporting vehicle; a second shelf which can at least temporarily put the transported object; and a displacing device which can reciprocate the transported object with respect to the first shelf and the port in a third direction, which is a direction along the processing apparatus and which is a direction coming close to and going away from the port, and which can reciprocate the transported object at a third direction position, which is away in the third direction at least by the transported object from the first shelf and the port, in a second direction crossing the third direction.

According to the second transfer apparatus of the present invention, firstly, the first shelf is disposed or constructed to be disposed to block the original transfer path in the middle which is from the transfer position at which the transporting vehicle transfers the transported object (typically, the transfer position at which the transporting vehicle performs longitudinal transfer in the vertical direction) to the port, as in the first shelf of the transfer apparatus of the present invention described above (hereinafter referred to as a “first transfer apparatus” as occasion demands). On the other hand, the displacing device can reciprocate the transported object with respect to the first shelf and the port in the third direction (e.g. horizontal one direction), which is the direction along the processing apparatus, which is, more specifically, a direction along the outer frame surface, outer casing surface, side surface, or side wall on which the port is disposed in the processing apparatus, and which is the direction coming close to and going away from the port. Correspondingly to this, the displacing device can reciprocate the transported object at the third direction position (e.g. horizontal direction position), which is away in the third direction from the first shelf and the port, in the second direction (e.g. vertical direction). Thus, with regard to the inner arrangement of the transfer apparatus, as in the first transfer apparatus, it is possible to include a path or space for displacing the transported object in the transfer apparatus in the third direction and the second direction, in an extremely small space.

Therefore, according to the second transfer apparatus of the present invention, if there is an obstacle in the first direction (i.e. in front) of the port when the transported object is transferred between the transporting vehicle and the first shelf, it is possible to disposed the first shelf in the original transfer path by bringing the first shelf close to the port in the third direction. In other words, the transfer apparatus can be disposed on the side of or right beside the port, or right beside the processing apparatus, in accordance with the placed position of the port in the processing apparatus. Thus, with regard to the outer arrangement of the transfer apparatus, the transfer apparatus does not occupy a space in front of the port of the processing apparatus in the transfer or the transported object and does not block a passage of an operator and equipment or the like in the space. In other words, it is possible to narrow the space in accordance with the arrangement of the transfer apparatus.

On the other hand, according to the second transfer apparatus of the present invention, it is possible to certainly reduce the protrusion of the transfer apparatus into the path for the passage of the operator and equipment or the like (i.e. including the aforementioned space), in comparison with the first transfer apparatus which brings the first shelf close to the port in the first direction.

In one aspect of the second transfer apparatus of the present invention, the transfer apparatus is disposed such that the third direction matches a direction along the track.

According to this aspect, when the transported object is transferred between the transporting vehicle and the first shelf, for example, if there is an obstacle in the first direction of the processing apparatus (specifically, in front of the port of the processing apparatus), it is possible to bring the transfer apparatus close to the port in the third direction, with the first shelf in front, in order to dispose the first shelf in the original transfer path. In other words, the transfer apparatus can be certainly disposed right beside the port, regardless of the placed position of the port in the processing apparatus. Thus, with regard to the outer arrangement of the transfer apparatus, the transfer apparatus does not occupy a space at all in front of the port of the processing apparatus and does not block the passage of the operator and equipment or the like in the space, by being displaced in the third direction which matches the direction along the track in the transfer of the transported object. In other words, it is possible to narrow the space in accordance with the arrangement of the transfer apparatus.

Incidentally, even the second transfer apparatus of the present invention can also adopt the same various aspects as those of the first transfer apparatus described above.

The nature, utility, and further features of this invention will be more clearly apparent from the following detailed description with reference to preferred embodiments of the invention when read in conjunction with the accompanying drawings briefly described below.

### BRIEF DESCRIPTION OF THE DRAWINGS

FIG. 1 is a perspective view showing the overall structure of a manufacturing system provided with a transfer apparatus in a first embodiment;

FIG. 2 is a cross sectional view in one direction showing the transfer apparatus in FIG. 1;

FIG. 3 is a cross sectional view in another direction showing the transfer apparatus in FIG. 1;

FIG. 4 is a flowchart showing a first transfer operation process in the first embodiment;

FIG. 5 is a flowchart showing a second transfer operation process in the first embodiment;

FIG. 6 is a cross sectional view in one direction showing the transfer apparatus of the present invention, which is different from the transfer apparatus in FIG. 1;

FIG. 7 is a top view showing the panoramic view of a transportation system in FIG. 1;

FIG. 8 is a cross sectional view in one direction showing the transfer apparatus of the present invention which is different from the transfer apparatuses in FIG. 1 and FIG. 6;

FIG. 9 are a top view and a side view showing a positioning device in the first embodiment;

FIG. 10 are a top view and a side view showing one example of the positioning device of the present invention which is different from the positioning device in FIG. 9;

FIG. 11 are a top view and a side view showing one example of the positioning device of the present invention which is different from the positioning devices in FIG. 9 and FIG. 10;

FIG. 12 are a top view and a side view showing one example of the positioning device of the present invention which is different from the positioning devices in FIG. 9 to FIG. 11;

FIG. 13 is a side view showing one example of the fixing device of the present invention;

FIG. 14 is a side view showing one example of the fixing device of the present invention;

FIG. 15 are a top view and a side view showing one example of the travelling device of the present invention;

FIG. 16 is a one-direction cross sectional view showing one example of the fixing device of the present invention;

FIG. 17 is a one-direction cross sectional view showing one example of the fixing device of the present invention;

FIG. 18 are a top view and a side view showing one example of the fixing device of the present invention;

FIG. 19 are a top view and a side view showing one example of the fixing device of the present invention;

FIG. 20 is a perspective view showing the overall structure of a manufacturing system provided with a transfer apparatus in a second embodiment;

FIG. 21 is a cross sectional view in another direction showing the transfer apparatus in FIG. 20;

FIG. 22 is a top view showing the transfer apparatus in FIG. 20;

FIG. 23 is a top view showing one example of the second transfer apparatus of the present invention which is different from the transfer apparatus in FIG. 20; and

FIG. 24 is a cross sectional view in another direction showing one example of the second transfer apparatus of the present invention which is different from the transfer apparatuses in FIG. 20 and FIG. 23.

### DETAILED DESCRIPTION OF THE PREFERRED EMBODIMENTS

Hereinafter, embodiments of the present invention will be explained with reference to the drawings.

### First Embodiment

### Structure of Manufacturing System

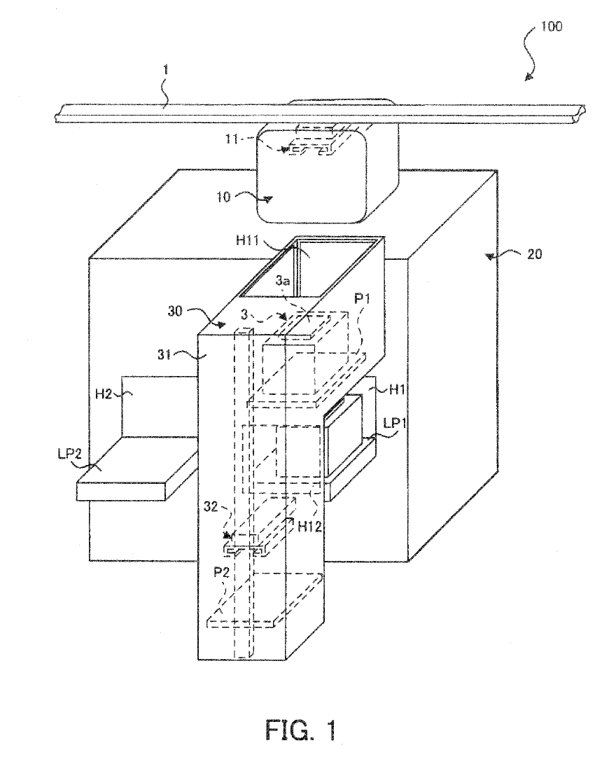

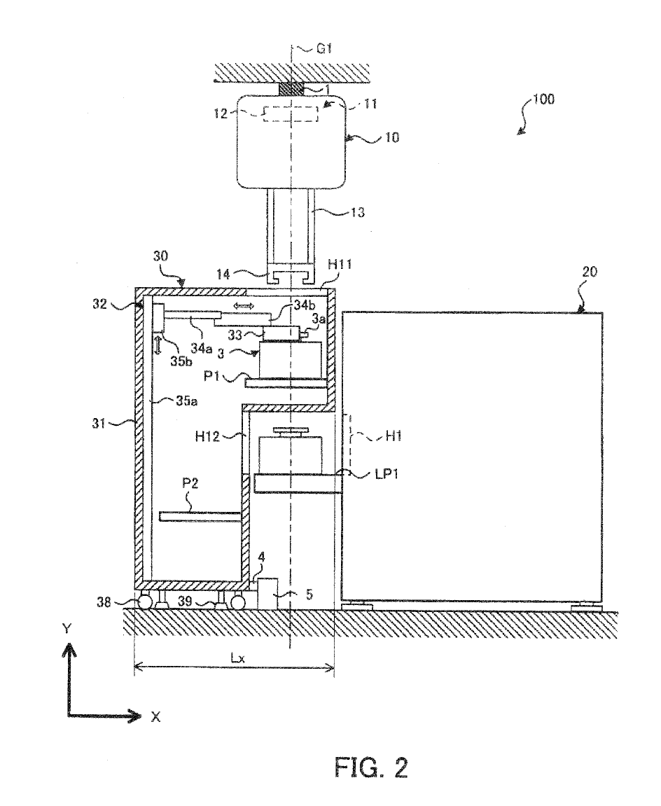

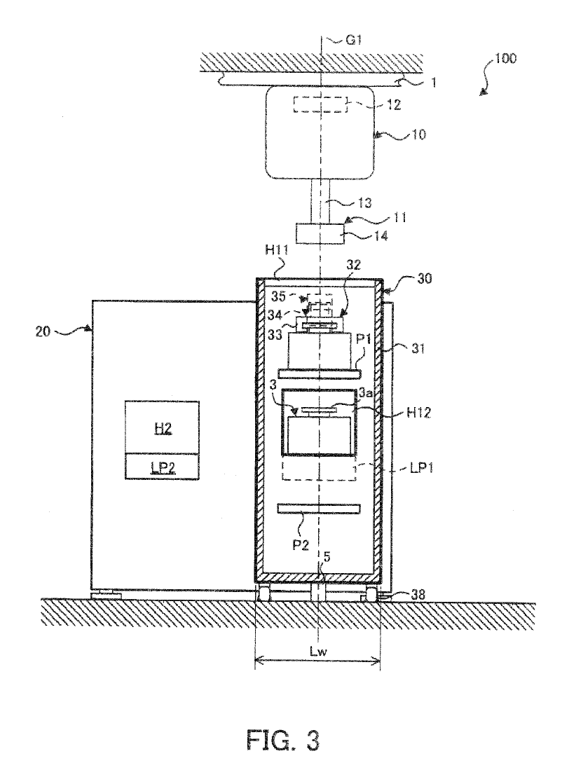

Firstly, the structure of a manufacturing system provided with a transfer apparatus in a first embodiment will be explained with reference to FIG. 1 to FIG. 3. FIG. 1 is a perspective view schematically showing the overall structure of the manufacturing system provided with the transfer apparatus in the first embodiment. FIG. 2 is a one-direction cross sectional view conceptually showing a cross section if the transfer apparatus in FIG. 1 is cut in one direction (i.e. an anteroposterior or front-back direction in FIG. 1). FIG. 3 is an another-direction cross sectional view conceptually showing a cross section if the transfer apparatus in FIG. 1 is cut in another direction (i.e. in a horizontal direction in FIG. 1).

In FIG. 1, a manufacturing system 100 is provided with a rail 1, a vehicle 10, a manufacturing apparatus 20, and a buffer apparatus 30. The manufacturing system 100 has a transportation function, which allows the vehicle 10 to travel along the rail 1 and which transports a FOUP3 (i.e. one example of the “transported object” of the present invention) which can accommodate or house a plurality of wafers (i.e. one example of the “processed object” of the present invention) to the manufacturing apparatus 20; and a manufacturing function, which performs various processes on the wafers in the FOUP3 by using the manufacturing apparatus 20, thereby manufacturing a semiconductor element.

The rail 1 serves as a track for the vehicle 10 traveling, as one example of the “track” of the present invention. The rail 1 is laid on a ceiling in a factory in which the manufacturing system 100 is placed.

The vehicle 10 is an OHT (Overhead Hoist Transport) driven by using a linear motor as power, as one example of the “transporting vehicle” of the present invention, and it is attached to the rail 1 in a suspended form. The vehicle 10 travels along the rail 1 and transports the FOUP3 not only to the manufacturing apparatus 20 but also to a stocker, OHT buffer, large-scaled stocker, or the like not illustrated. The operations, such as transportation and travel, of the vehicle 10 are controlled by a not-illustrated controller in the manufacturing system 100. Incidentally, for convenience of explanation, only one vehicle 10 is illustrated on the rail 1; however, typically, more vehicles 10 (e.g. several tens or several hundreds) are provided.

The vehicle 10 is provided therein with a hoist mechanism 11, which has a winding device 12 having a not-illustrated winding shaft, a winding belt 13, and a gripper 14. One end of the winding belt 13 is fixed to the winding shaft, and the other end is fixed to the gripper 14. The winding device 12 rotates the winding shaft by using a not-illustrated motor as power, and it can wind up or wind off the winding belt 13 from the one end. The gripper 14 can be displaced into a holding state in which an upper part (i.e. flange) 3a of the FOUP3 is held on the both ends of the gripper 14 which are bent inward, or into a release state in which the flange 3a of the FOUP3 is released. By the winding belt 13 being wound up or wound off, the hoist mechanism 11 having such a structure hoists the gripper 14 in a vertical direction below the rail 1 and displaces the gripper 14 at a vertical position, thereby transferring the FOUP3 from the vehicle 10 side to the buffer apparatus 30 side described later, or from the buffer apparatus 30 side to the vehicle 10 side. As described above, in the embodiment, a transfer path by the vehicle 10 extends downward in the vertical direction from the transfer position of the vehicle 10 (i.e. a stop position shown in FIG. 1) to longitudinally transfer the FOUP3.

The manufacturing apparatus 20 performs a predetermined process on the FOUP3, and actually on the wafers accommodated in the FOUP3, as one example of the “processing apparatus” of the present invention. The manufacturing apparatus 20 is provided therein with a not-illustrated processing device for performing the predetermined process on the wafers, and two openings H1 and H2 which can bring in and out the wafer to be processed, in the processing device. The manufacturing apparatus 20 is provided with two load ports LP1 and LP2 which function as ports for transferring the FOUP3 with the buffer apparatus 30, in the exterior adjacent to each of the two openings H1 and H2 and below the rail 1. The manufacturing apparatus 20 is provided with a not-illustrated inner and outer transfer mechanism which brings in and out the wafers, which are in the FOUP3 transferred to each of the two load ports LP and LP2, in the processing device through the opening H1 or H2. The operations, such as bringing in and out the wafers, and the predetermined process, of the manufacturing apparatus 20 are controlled by the controller in the manufacturing system 100. Incidentally, for convenience of explanation, only one manufacturing apparatus 20 is illustrated below the rail 1; however, typically, more manufacturing apparatuses 20 (e.g. several or several hundreds) are provided which perform different processes on the FOUP3. Moreover, the number of the openings and the load ports are not limited to two but may be three or more, and the arrangement thereof can be also in various aspects.

The buffer apparatus 30 transfers the FOUP3 with the vehicle 10 and with the manufacturing apparatus 20 such that the FOUP3 is efficiently transferred between the vehicle 10 and the manufacturing apparatus 20, as one example of the “transfer apparatus” of the present invention. Incidentally, for convenience of explanation, only one buffer apparatus 30 corresponding to the one load port LP1 is illustrated on the manufacturing apparatus 20 provided with the two load ports LP1 and LP2; however, two buffer apparatuses 30 each corresponding to respective one of the load ports LP1 and LP2 may be provided as another embodiment.

The buffer apparatus 30 is provided with a main body part 31, an OHT port P1, a buffer P2, and a transfer mechanism 32. In FIG. 2, the main body part 31 is an inverted L-shaped case which can be installed or attached from the front side (i.e. the left side in FIG. 2) to the load port LP1. The main body part 31 is disposed such that a longitudinal direction is a direction perpendicular to the orientation of the rail 1 (i.e. one example of the “horizontal one direction” of the present invention and an X direction in FIG. 2) in the installation or attachment. The main body part 31 has a length (i.e. a length Lx in FIG. 2) which allows at least two FOUPs 3 to be disposed in the X direction and has a length (i.e. a length Lw in FIG. 3) which allows at least one FOUP3 to be disposed in the orientation of the rail 1. Incidentally, for convenience of explanation, the structure of the buffer apparatus 30 in which the main body part 31 is attached to the load port LP1 will be explained.

Within the main body part 31, there are placed the OHT port P1, the buffer P2, and the transfer mechanism 32. The main body part 31 is provided with an opening H11 which can transfer the FOUP3 between the OHT port P1 and the vehicle 10, on an upper surface corresponding to the vertical direction of the rail 1 (i.e. shown by an alternate long and short dash line G1 in FIG. 2 and FIG. 3). Moreover, the main body part 31 is provided with an opening H12 which can transfer the FOUP3 with the load port LP1 (i.e. the manufacturing apparatus 20), on the side surface adjacent to the FOUP3 put on the load port LP1.

The OHT port P1 functions as a port of the buffer apparatus 30 for transferring the FOUP3 on which the predetermined process is to be performed or has been performed in the manufacturing apparatus 20, through the opening H11 with the vehicle 10, as one example of the “first shelf” of the present invention. The OHT port P1 is placed above the load port LP1 in the vertical direction of the rail 1 such that the vehicle 10 can transfer the FOUP3 in a short time by longitudinal transfer (i.e. transfer which allows the FOUP3 to be displaced only in the vertical direction in the transfer). As is clear from FIG. 1 to FIG. 3, the OHT port P1 exists at a position to block the transfer path (i.e. the “original transfer path” of the present invention) when the vehicle 10 longitudinally transfers the FOUP3 with respect to the load port LP1 of the manufacturing apparatus 20 if the buffer apparatus 30 is removed. Thus, as viewed from the vehicle 10, it is only necessary to perform the transfer operation on the port which is at the same position in planar view, i.e. which is below the transfer position in the vertical direction, regardless of the presence of the buffer apparatus 30. In other words, if there is only a difference in the height of the port as viewed from the vehicle 10, the control with respect to the transfer operation by the vehicle 10 is almost the same, regardless of the presence of the buffer apparatus 30, so that it is extremely useful in practice.

The buffer P2 functions as a temporary put shelf for at least temporarily putting the FOUP3 on which the predetermined process is to be performed or has been performed in the manufacturing apparatus 20, as one example of the “second shelf” of the present invention. The buffer P2 is placed below the load port LP1 in the vertical direction of the rail 1 and in the X direction so that it does not block the transfer of the FOUP3 by the transfer mechanism 32 described later.

The transfer mechanism 32 is displaced among the load port LP1, the OHT port P1, and the buffer P2 and transfers the FOUP3 among them, as one example of the “displacing device” of the present invention. The transfer mechanism 32 is provided with a holding device 33, a horizontal displacement mechanism 34, and a hoist mechanism 35, and it is placed on the front side of the main body part 31 (i.e. the left side in FIG. 2). The holding device 33 is one example of the “holding device” of the present invention and has a pair of planar portions. The planar portions enter below the flange 3a in the X direction and support the both ends of the flange 3a from the below, thereby holding the FOUP3. As shown in FIG. 2, the horizontal displacement mechanism 34 is one example of the “horizontal displacing device” of the present invention, and it is provided with a rail part 34a placed such that the longitudinal direction is parallel to the X direction; and a slide part 34b which can be slid in the X direction along the rail part. To the tip of the horizontal transfer mechanism 34 (i.e. the end on the manufacturing apparatus 20 side of the slide part 34b), the holding device 33 is fixed. The hoist mechanism 35 is one example of the “vertical displacing device” of the present invention, and it is provided with a turn belt 35a which can turn in the vertical direction by using a not-illustrated motor as a power source; and a hoist device 35b which is displaced in the vertical direction with the turn of the turn belt. To the hoist device 35b, one end of the rail part 34a is fixed.

The transfer mechanism 32 displaces the holding device 33 in the X direction (i.e. one example of the “first direction” of the present invention) and in the vertical direction (e.g. one example of the “second direction” of the present invention) among the load port LP1, the OHT port P1, and the buffer P2 by the mutual operation performed by the horizontal transfer mechanism 34 and the hoist mechanism 35 described above, and the transfer mechanism 32 holds or releases the FOUP3 on the holding device 33, thereby transferring the FOUP3 among them. The operations, such as the displacement of the transfer mechanism 32 and the transfer of the FOUP3, are controller by the controller in the manufacturing system 100.

<First Transfer Operation Process in Manufacturing System>

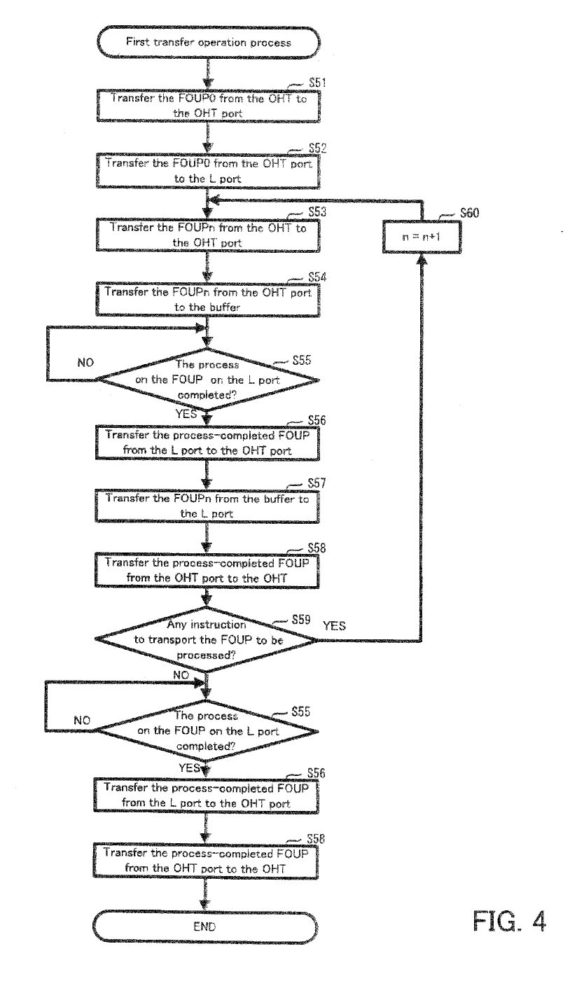

Next, the transfer operation between the transporting vehicle and the processing apparatus via the transfer apparatus in the manufacturing system 100 will be explained with reference to FIG. 4. FIG. 4 is a flowchart showing the first transfer operation process in the first embodiment.

In FIG. 4, firstly, an instruction to transport the FOUP 3 to the manufacturing apparatus 20 is given to the vehicle 10 which holds the FOUP 3 on which the process in the manufacturing apparatus 20 is to be performed, by the controller in the manufacturing system 100. Here, it is assumed that the FOUP which is the first transportation target is “FOUP0”. After that, on the basis of the instruction from the controller, the vehicle 10 (i.e. written as “OHT” in FIG. 4) travels along the rail 1 and stops at a predetermined transfer position corresponding to the buffer apparatus 30 (i.e. stop position shown in FIG. 1 to FIG. 3). Then, by the hoist mechanism 11, the gripper 14 holding the FOUP0 is lowered in the vertical direction through the opening H11 in the buffer apparatus 30 from the inside of the vehicle 10, and the FOUP0 is released from the gripper 14 at the vertical position at which the FOUP0 is in contact with the upper surface of the OHT port P1. In other words, the FOUP0 is transferred from the vehicle 10 to the OHT port P1 (step S51).

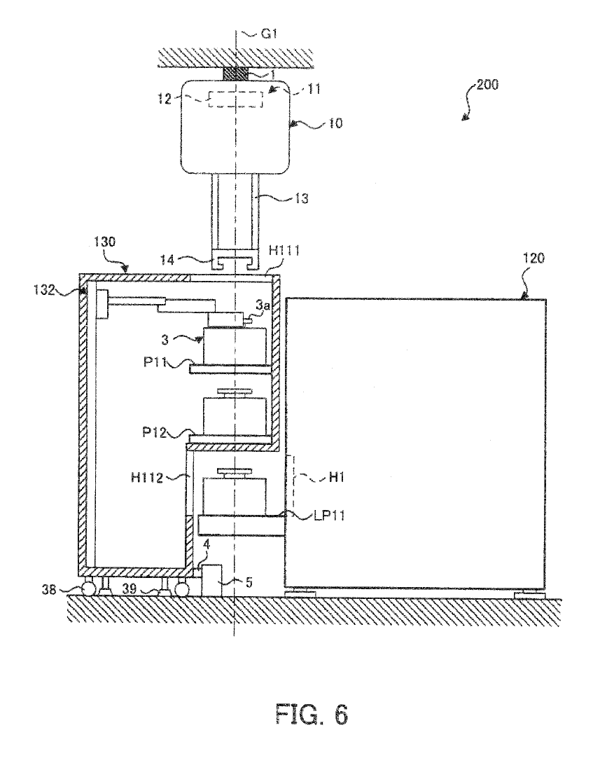

Then, in the buffer apparatus 30, the holding device 33 is displaced to below the flange 3a of the FOUP0 on the OHT port P1 by the horizontal displacement mechanism 34, and the hoist mechanism 35 before the holding device 33 is raised until it comes into contact with the lower surface of the flange 3a. In this manner, the FOUP0 is held by the holding device 33. Then, the holding device 33 which holds the FOUP0 is displaced to above the load port LP1 (i.e. written as “L port” in FIG. 6) through the opening H12 before the holding device 33 is lowered until the FOUP0 comes into contact with the load port LP1. In this manner, the FOUP0 is transferred from the OHT port P1 to the load port LP1 (step S52). After that, the holding device 33 is horizontally displaced to the side of the FOUP0 on the load port P1, and the FOUP0 is released from the holding device 33. The wafers in the FOUP0 transferred to the load port LP1 are temporarily accommodated in the manufacturing apparatus 20, and the predetermined process is performed inside before the wafers are put into the FOUP0 on the load port LP1 again.

Then, on the basis of a new instruction from the controller, as in the operation in the step S51, a FOUPn (i.e. “n” is a variable indicating the order that the FOUP3 is transported) which is a second transportation target is transferred onto the OHT port P1 from the vehicle 10 which has arrived at a new transfer position which is different from the previous one (step S53). Then, the holding device 33 which holds the FOUPn on the OHT port P1 is displaced to above the buffer P2 by the horizontal displacement mechanism 34 and the hoist mechanism 35 before the holding device 33 is lowered until the FOUPn comes into contact with the buffer P2. In this manner, the FOUPn is transferred from the OHT port P1 to the buffer P2 (step S54).

Then, it is judged whether or not the predetermined process in the manufacturing apparatus 20 has been completed on the FOUP (here, FOUP0) on the load port LP1, by the controller (step S55). As a result of the judgment, if it is judged that the predetermined process has not been completed (the step S55: NO), it becomes in a standby state until the predetermined process has been completed.

On the other hand, as a result of the judgment in the step S55, if it is judged that the predetermined process has been completed on the FOUP (here, FOUP0) on the load port LP1 (the step S55: YES), the FOUP on which the process has been completed is transferred from the load port LP1 to the OHT port P1 by the transfer mechanism 32 (step S56). At this time, the FOUP on which the process has been completed is displaced to the OHT port P1 such that it slips through above the FOUPn put on the buffer P2. Then, the FOUPn is transferred from the buffer P2 to the load port LP1 by the transfer mechanism 32 which is unloaded (i.e. which no longer holds the FOUP3) (step S57).

After that, on the basis of the instruction from the controller, the vehicle 10 of the transfer mechanism 32 which is unloaded (i.e. which no longer holds the FOUP3) is stopped at a predetermined transfer position. Then, the unloaded gripper 14 is lowered in the vertical direction through the opening H11 by the hoist mechanism 11, and the FOUP on which the process has been completed is held by the gripper 14. In other words, the FOUP on which the process has been completed is transferred from the OHT port P1 to the vehicle 10 (step S58). After that, the gripper 14 which holds the FOUP on which the process has been completed is raised by the hoist mechanism 11 and is held within the vehicle 10. In this manner, the vehicle 10 becomes in the state that it can travel.

Then, it is judged whether or not there is an instruction to transport the FOUP3 to be processed, by the controller (step S59). As a result, if it is judged that there is the instruction (the step S59: YES), the FOUP which is a third transportation target is set to “FOUPn+1” (step S60). Then, as in the operation in the step S51, the FOUPn+1 which is the third transportation target is transferred to the OHT port P1 from the vehicle 10 which has arrived at a new transfer position which is different from the previous one, as the operation in the step S53 again. After that, the FOUPn+1 is transferred from the OHT port P1 to the buffer P2, as the operations in the step S54 to the step S59. Then, it is judged whether or not the predetermined process has been completed on the FOUP (here, FOUPn) on the load port LP1, and when it is judged that the predetermined process has been completed, the FOUP on which the process has been completed is transferred from the load port LP1 to the OHT port P1. Then, after the FOUPn+1 is transferred from the buffer P2 to the load port LP1, if the FOUP on which the process has been completed is transferred from the OHT port P1 to the vehicle 10, it is judged whether or not there is another instruction to transport the FOUP3 to be processed.

On the other hand, as a result of the judgment in the step S59, if it is judged that there is no further instruction (the step S59: NO), it is judged whether or not the predetermined process has been completed on the FOUP (here, FOUPn+x (i.e. “n+x” is shown by the FOUP3 which is the last transportation target)) on the load port LP1 as the operations in the steps S55, S56, and S58. If the predetermined process has been completed, when the last FOUP on which process has been completed is transferred from the load port LP1 to the OHT port P1, the last FOUP is transferred from the OHT port P1 to the vehicle 10. By this, all the FOUPs3 on which the predetermined process is performed in the manufacturing apparatus 20 are transferred to the vehicle 10 through the buffer apparatus 30, and the series of first transfer operation process is ended.

As described above, according to the first transfer operation process in the embodiment, it is possible to improve the operating rate of the manufacturing apparatus 20 by using the buffer P2 for replacing the FOUP3 on the load port LP1 to efficiently replace the FOUP3 on which the process has been completed by the FOUP3 to be processed from now.

Incidentally, the operation in the step S58 may be performed in tandem with the step S57 if it is after the FOUP3 on which the process has been completed is transferred to the OHT port P1 as the operation in the step S56.

<Second Transfer Operation Process in Manufacturing System>

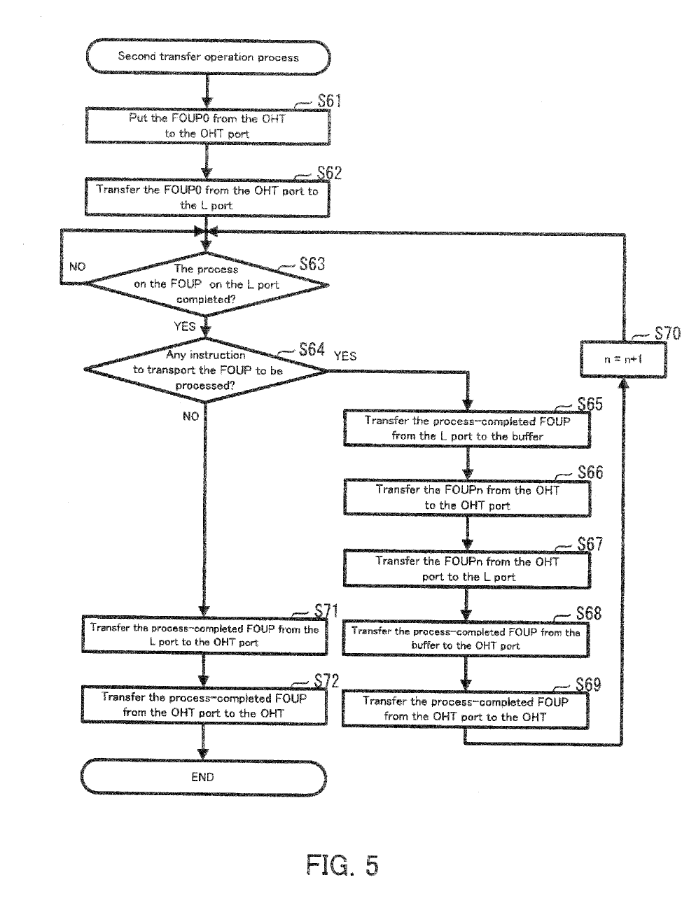

Next, another transfer operation which is different from the first transfer operation in FIG. 4 will be explained with reference to FIG. 5. FIG. 5 is a flowchart showing a second transfer operation process in the first embodiment.

In FIG. 5, firstly, as in the case of FIG. 4, an instruction to transport the FOUP3 to the manufacturing apparatus 20 is given to the vehicle 10 which holds the FOUP 3 on which the process in the manufacturing apparatus 20 is to be performed, by the controller in the manufacturing system 100. Here, it is assumed that the FOUP which is the first transportation target is “FOUP0”. After that, on the basis of the instruction from the controller, the FOUP0 is transferred from the vehicle 10 (i.e. written as “OHT” in FIG. 5 as in the case of FIG. 4) to the OHT port P1 (step S61). Then, in the buffering apparatus 30, the FOUP0 is transferred from the OHT port P1 to the load port LP1 (i.e. written as “L port” in FIG. 5 as in the case of FIG. 4) by the transfer mechanism (step S62). Then, it is judged whether or not the predetermined process in the manufacturing apparatus 20 has been completed on the FOUP (here, FOUP0) on the load port LP1 (step S63). As a result of the judgment, if it is judged that the predetermined process has not been completed (the step S63: NO), it is continued until the predetermined process has been completed.

On the other hand, as a result of the judgment in the step S63, if it is judged that the predetermined process has been completed on the FOUP (here, FOUP0) on the load port LP1 (the step S63: YES), it is judged whether or not there is an instruction to transport the FOUP3 to be processed, by the controller (step S64). As a result, if it is judged that there is the instruction (the step S64: YES), the FOUP on which the process has been completed is transferred from the load port LP1 to the buffer P2 by the transfer mechanism 32 (step S65). Then, if the FOUPn which is the second transportation target is transferred from the vehicle 10 to the OHT port P1 on the basis of a new instruction from the controller (step S66), the FOUPn is directly transferred from the OHT port P1 to the load port LP1 (step S67). In other words, as opposed to the case of the first transfer operation process described above, the FOUPn before the processing is not temporarily put on the buffer P2. Then, the FOUP on which the process has been completed (here, FOUP0) is transferred from the buffer P2 to the OHT port P1 (step S68). After that, the FOUP is transferred from the OHT port P1 to the vehicle 10 (step S69). Here, the FOUP which can be the third transportation target is set to “FOUPn+1” (step S70).

Then, as in the operation in the step S63 and the step S64 again, it is judged whether or not the predetermined process in the manufacturing apparatus 20 has been completed on the FOUP on the load port LP1, and when it is judged that the predetermined process has been completed, it is judged whether or not there is an instruction to transport the FOUP3 to be processed next.

On the other hand, as a result of the judgment in the step S64, if it is judged that there is no further instruction (the step S64: NO), the FOUP on which the process has been completed is transferred from the load port LP1 to the OHT port P1 (step S71), and then, the FOUP is transferred from the OHT port P1 to the vehicle 10 (step S72). By this, as in the first transfer operation in FIG. 4, all the FOUPs3 on which the predetermined process is performed in the manufacturing apparatus 20 are transferred to the vehicle 10 through the buffer apparatus 30, and the series of second transfer operation process is ended.

As described above, according to the second transfer operation process in the embodiment, if the predetermined process has been completed in the manufacturing apparatus 20, the FOUP3 on the load port LP1 is removed immediately after that, and the FOUP to be processed next is put onto the load port LP1 (actually, the wafers in the FOUP3 are brought into the manufacturing apparatus 20). Therefore, it is possible to further improve the operating rate of the manufacturing apparatus 20.

Incidentally, according to the first embodiment, the OHT port P1 is disposed above the load port LP1 in the vertical direction of the rail 1, and the buffer P2 is disposed below the load port LP1 in the vertical direction and in the X direction; however, the arrangement of the buffer is not limited to this. FIG. 6 is a one-direction cross sectional view for explaining one example of the arrangement which is different from the arrangement of the second shelf in the embodiment. In FIG. 6, in a buffering apparatus 130, a buffer P12 is disposed between an OHT port P11 and a load port LP11 in a vertical direction G1 of the rail 1. A transfer mechanism 132 is displaced among the buffer P12, the OHT port P11, and the load port LP11, and the FOUP3 can be transferred among them. By this, even in the arrangement of the buffer P12, it is possible to obtain the same operation and effects as those in the buffer apparatus 30 in the first embodiment described above.

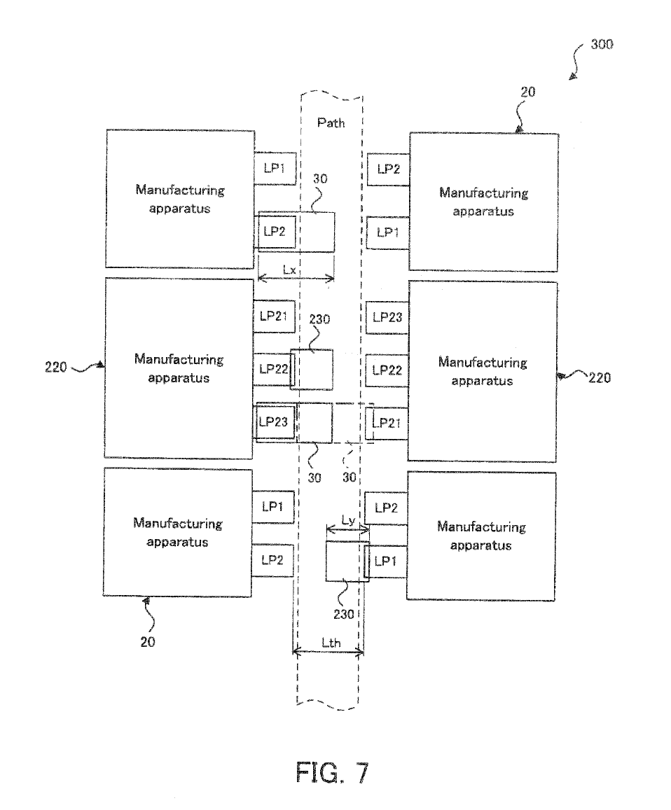

Incidentally, according to the first embodiment, the buffer apparatus 30 has the length Lx which allows at least two FOUPs 3 to be disposed in the X direction (i.e. the longitudinal direction of the buffer apparatus 30, which is one example of the “first direction” of the present invention) which crosses the orientation of the rail 1 at right angles in the state that it is attached to the load port LP1; however, the form of the buffer apparatus 30 is not limited to this. FIG. 7 is a top view schematically showing the panoramic view of a transportation system provided with the transfer apparatus in the embodiment. In FIG. 7, a transportation system 300 is provided with a plurality of manufacturing apparatuses 20 and 220. The plurality of manufacturing apparatuses 20 and 220 are provided with a path (i.e. a hatching portion in FIG. 7) which is used for a system administrator or the like who administrates the transportation system in the failure or maintenance of any element, to carry in and out broken equipment or maintenance equipment, or to place the transfer apparatus of the present invention. The plurality of manufacturing apparatuses 20 and 220 are placed in two lines such that the path is between them and such that the load ports LP1, LP2, and LP21 to LP23 are disposed on the path side. As shown in FIG. 7, the width of the path Lth (i.e. the shortest distance between the load ports LPs in a pair of manufacturing apparatuses opposed to each other across the path) is less than a length La in the X direction of the buffer apparatus 30 in the first embodiment. Thus, the buffer apparatus 30 cannot be attached to any of the load ports.

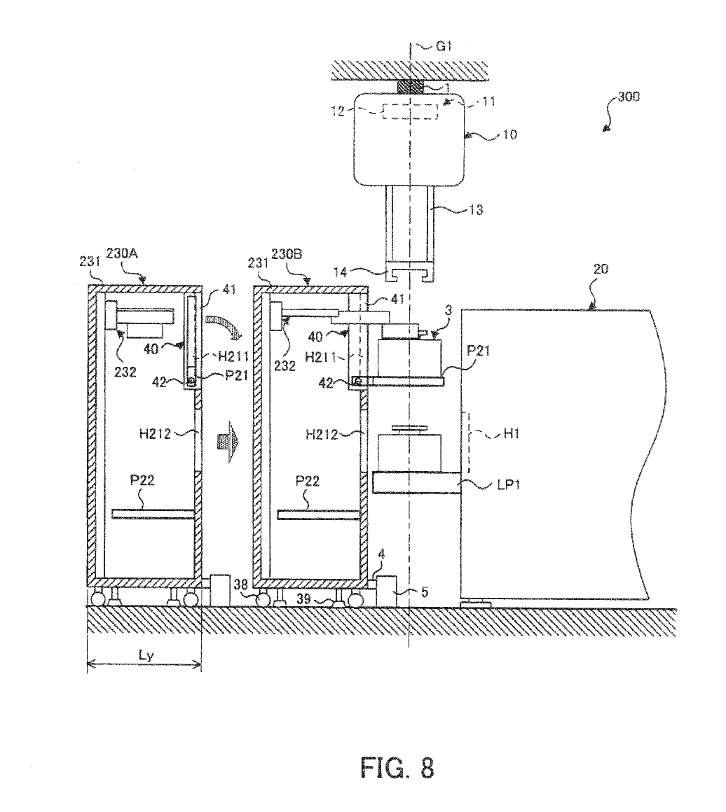

FIG. 8 is a one-direction cross sectional view for explaining one example of the outer shape which is different from the outer shape of the transfer apparatus in the first embodiment. In FIG. 8, a buffer apparatus 230 which is also shown in FIG. 7 has a length Ly obtained by combining a length of a space required for a transfer mechanism 232 to be displaced in the vertical direction and a length which allows one FOUP3 to be disposed, in the X direction, before and after it is attached to the load port LP1 (i.e. except the attachment). The length Ly is less than the width of the path Lth. This is because a storage mechanism 40 which can be stored in a main body part 231 is provided before and after an OHT port P21 is attached to the load port LP1. The storage mechanism 40 is provided with a storage device 41 and a hinge device 42. The accommodation device 41 is placed in the vicinity of an opening 211 which can let the FOUP3 through by the transfer of the transfer mechanism 232 in the main body part 231, and the accommodation device 41 accommodates or houses the OHR port P21 in the perpendicular direction. The hinge 42 rotatably connects one end of the OHT port P21 with the accommodation device 41, and the hinge 42 can displace the OHT port P21 between a transfer position opposed to the rail 1 and an accommodation position at which it is accommodated in the accommodation device 41.

As shown in FIG. 8, when the buffer apparatus 230 is attached to the load port LP1, the buffer apparatus 230 is displaced on the path in FIG. 7 in the state that the OHT port P21 is accommodated at the accommodation position (i.e. the state of a buffer mechanism 230A in FIG. 8), and it is disposed on the front side (i.e. the left side in FIG. 8) of the load port LP1 which is an attachment target. Then, the buffer apparatus 230 is attached to the load port LP1 in the state that the OHT port P21 is displaced to the transfer position (i.e. the state of a buffer mechanism 230B in FIG. 8). In the attachment, the OHT port P21 is disposed in the vertical direction of the rail 1. As described above, by providing the accommodation mechanism 40 which can accommodate the OHT port P21, it is possible to make the buffer apparatus compact and light. Therefore, it facilitates the displacement of the buffer apparatus, and it increases the degree of freedom in the attachment of the buffer apparatus.

<Method of Positioning Transfer Apparatus>

Next, a method of positioning the transfer apparatus of the present invention will be explained with reference to FIG. 9 to FIG. 15. Each of FIG. 9 is a top view or a side view showing one example of a positioning device for positioning the buffer apparatus with respect to the manufacturing apparatus 20 in FIG. 1 to FIG. 3.

FIG. 9A is a top view showing the buffer apparatus 30 in the first embodiment poisoned (in other words, attached) with respect to the manufacturing apparatus 20 in the first embodiment, and FIG. 9B is a side view showing the buffer apparatus 30 in FIG. 9A. In FIG. 9A, the buffer apparatus 30 is provided with a cylindrical abutting part 4 on the side surface on the load port LP1 side. In contrast, on a floor surface between the buffer apparatus 30 and the manufacturing apparatus 20 (i.e. below the load port LP1 in FIG. 1 to FIG. 3), there is placed a poisoning block 5 (i.e. one example of the “positioning device” of the present invention) in which one surface is formed in a tapered shape. The buffer apparatus 30 is set into a displacement state described later when it is attached to the load port LP1, and the buffer apparatus 30 is displaced in the X direction until the abutting part 4 abuts on the positioning block 5. By this, the buffer apparatus 30 is positioned with respect to the manufacturing apparatus 20.

In FIG. 9B, the buffer apparatus 30 is provided with a plurality of travel roller 38 for displacement and a plurality of legs 39 each of which makes a pair with respective one of the plurality of travel rollers 38, on the bottom surface. Each travel roller 38 is provided with a caster 38a and a jack bolt 38b which can extend and contract the caster 38a in the perpendicular direction. Each leg 39 is provided with a support part 39a which is in contact with the floor surface and which supports the main body of the buffer apparatus 30; and an adjuster 39b which fixes the support part 39a to the floor surface of the buffer apparatus 30 without displacing the support part 39a. When the buffer apparatus 30 is displaced, the jack bolts 38a are tightened counterclockwise. Then, the buffer apparatus 30 becomes in the state that the casters 38a extending from the main body of the buffer apparatus 30 come into contact with the floor surface and that the support parts 39a are released from the floor surface (i.e. the displacement state of the buffer apparatus). In this state, the buffer apparatus 30 can be easily displaced by rotating the caster 38a. Moreover, by the abutting part 4 abutting on the positioning block 5, the jack bolts 38b are tightened clockwise when the buffer apparatus 30 positioned with respect to the manufacturing apparatus 20 is fixed. Then, the buffer apparatus becomes in the state that the casters 38a contracted toward the main body of the buffer apparatus 30 are released from the floor surface and that the support parts 39a are in contact with the floor surface (i.e. the fixed state of the buffer apparatus). In this state, the buffer apparatus 30 is stably disposed.

FIG. 10(a) is a top view showing the buffer apparatus 130 positioned with respect to the load port LP1, and FIG. 10(b) is a side view showing the buffer apparatus 130 in FIG. 10(a). Incidentally, in FIG. 10, the same constituent elements as in the case of the buffer apparatus 30 in FIG. 9 described above will carry the same referential numerals, and the explanation thereof will be omitted.

In FIG. 10(a), the buffer apparatus 130 is provided with an abutting part 104 in which an abut surface is formed in a tapered shape, on the side surface on the load port LP1 side. In contrary, on a floor surface between the buffer apparatus 130 and the manufacturing apparatus 20 (i.e. below the load port LP1 in FIG. 1 to FIG. 3), there is placed a cylindrical poisoning pin 105 (i.e. one example of the “positioning device” of the present invention). The buffer apparatus 130 is set into the displacement state when it is attached to the load port LP1, and the buffer apparatus 130 is displaced in the X direction until the abutting part 104 abuts on the positioning pin 105. By this, the buffer apparatus 130 is positioned with respect to the manufacturing apparatus 20.

FIG. 11(a) is a top view showing the buffer apparatus 230 positioned with respect to the load port LP1, and FIG. 11(b) is a side view showing the buffer apparatus 230 in FIG. 11(a). Incidentally, in FIG. 11, the same constituent elements as in the case of the buffer apparatus 30 in FIG. 9 described above will carry the same referential numerals, and the explanation thereof will be omitted.

In FIG. 11(a), the buffer apparatus 230 is provided with an abutting part 204 in which an abut surface is formed in a tapered shape, on the side surface on the load port LP1 side. In contrary, on a floor surface between the buffer apparatus 230 and the manufacturing apparatus 20 (i.e. below the load port LP1 in FIG. 1 to FIG. 3), there are placed two cylindrical poisoning pins 205a and 205b (i.e. one example of the “positioning device” of the present invention). The buffer apparatus 230 is set into the displacement state when it is attached to the load port LP1, and the buffer apparatus 230 is displaced in the X direction until the two positioning pins 205a and 205b engage with the abutting part 204. By this, the buffer apparatus 230 is positioned with respect to the manufacturing apparatus 20, more accurately than in the case of one positioning pin.

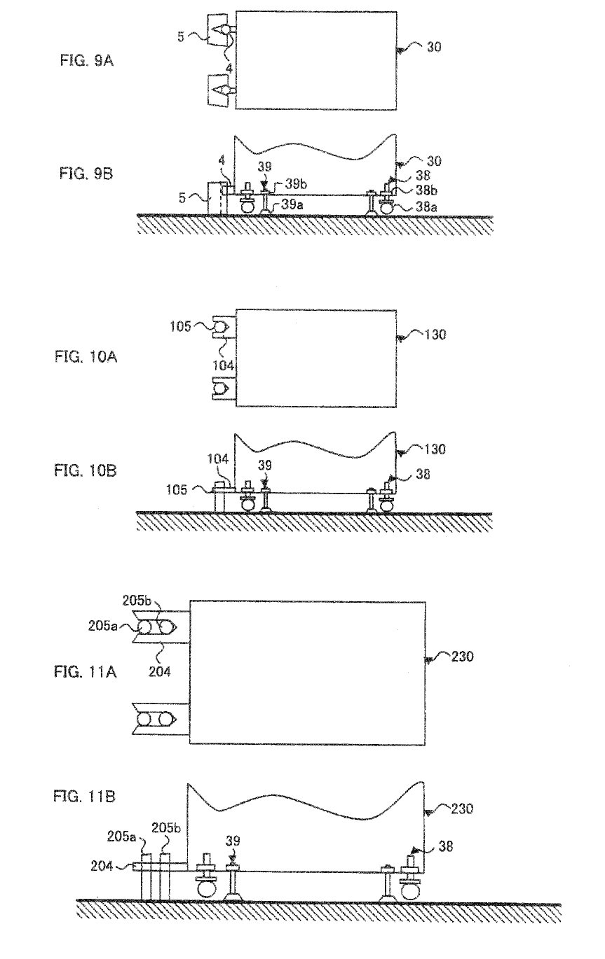

FIG. 12(a) is a top view showing a buffer apparatus 330 positioned with respect to the load port LP1, and FIG. 12(b) is a side view showing the buffer apparatus 330 in FIG. 12(a). Incidentally, in FIG. 12, the same constituent elements as in the case of the buffer apparatus 130 in FIG. 10 described above will carry the same referential numerals, and the explanation thereof will be omitted.

In FIG. 12(a), the buffer apparatus 330 is provided with not only the abutting part 104 which abuts on the positioning pin 105 (i.e. one example of the “positioning device” of the present invention) but also an engagement part 36 (i.e. one example of the “positioning device” and the “fixing device” of the present invention) which can certainly lock the main body of the buffer apparatus 330 on the positioning pin 105. One end of the engagement part 36 is rotatably mounted on the side surface on the load port LP1 side, and the other end is bent so that it engages with the positioning pin 105 at a predetermined turn position. The buffer apparatus 330 is provided with a lock lever 38 on the side surface on the opposite side of the load port LP1. The lock lever 37 can be operated by the system administrator, and it can displace the engagement part 36 between a lock position which is the aforementioned predetermined turn position and at which the main body of the buffer apparatus 330 is locked with respect to the positioning pin 105 (i.e. shown by the engagement part 36 in a dashed line in FIG. 12A) and a non-lock position which is a turn position initially set and at which the main body of the buffer apparatus 330 is released (i.e. shown by the engagement part 36 in a solid line in FIG. 12A). In the attachment to the load port LP1, firstly, the buffer apparatus 330 is set into the displacement state, and the lock lever 37 is displaced to the non-lock position. Then, the buffer apparatus 330 is displaced in the X direction until the abutting part 104 abuts on the positioning pin 105, and then, the engagement part 36 is displaced to the lock position. After that, the buffer apparatus 330 is set into the fixed state and is fixed at the position that the buffer apparatus is positioned. By this, the buffer apparatus 330 is positioned with respect to the manufacturing apparatus 20, more accurately and certainly than the case where it is positioned only by the abutting part 104.

<Method of Fixing Transfer Apparatus>

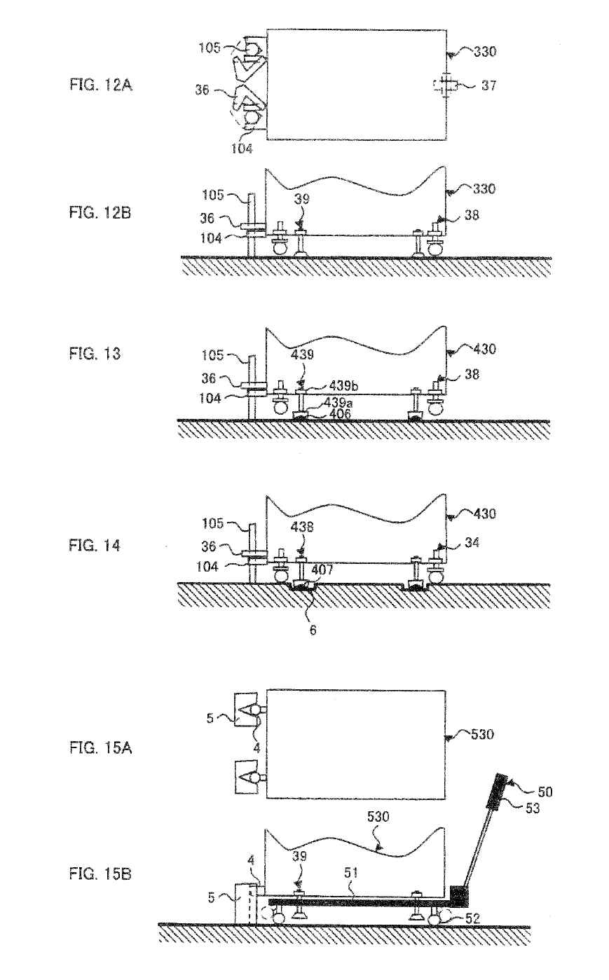

FIG. 13 is a side view showing a buffer apparatus 430 positioned with respect to the load port LP1. Incidentally, in FIG. 13, the same constituent elements as in the case of the buffer apparatus 330 in FIG. 12 described above will carry the same referential numerals, and the explanation thereof will be omitted.

In FIG. 13, on a floor surface on which a buffer apparatus 430 positioned with respect to the manufacturing apparatus 20 is disposed, there are placed convex cones 406 (i.e. one example of the “fixing device” of the present invention). In contrast, a plurality of legs 439 of the buffer apparatus 430 have support parts 439a which are formed in a concave shape and which engage with the cones 406 on their contact surfaces with floor surface. When the buffer apparatus 430 is displaced, the jack bolts 38b are tightened counterclockwise, and the extended casters 38a come into contact with the floor surface. At the same time, the support parts 439a are set into the aforementioned displacement state that they are released from the floor surface (i.e. the floor surface including the portions in which the cones 406 are placed). When the buffer apparatus 430 positioned with respect to the manufacturing apparatus 20 is fixed, the jack bolts 38b are tightened clockwise, and the contracted casters 38a are released from the floor surface. At the same time, the support parts 439a are set into the aforementioned fixed state that they engage with the cones 406. By this, the buffer apparatus 430 is disposed more stably than the case of a simple flat floor surface.

FIG. 14 is a side view showing the buffer apparatus 430 positioned with respect to the load port LP1, as in FIG. 13. Incidentally, in FIG. 14, the same constituent elements as in the case of the buffer apparatus 430 in FIG. 13 described above will carry the same referential numerals, and the explanation thereof will be omitted.

In FIG. 14, on a floor surface on which the buffer apparatus 430 positioned with respect to the manufacturing apparatus 20 is disposed, there are placed the same cones 407 (i.e. one example of the “fixing device” of the present invention) as the cones 406 in FIG. 13. However, portions 6 of the floor surface in which the cones 407 are placed are lower than the original floor surface on which the manufacturing apparatus 20, the buffer apparatus 430, and the like are placed, by the height of the cones 407. This is to avoid a danger to a person, such as the system administrator tripping over or falling on the cones which project from the floor surface. As in the case of FIG. 13, when the buffer apparatus 430 is displaced, the jack bolts 38b are tightened counterclockwise, and the extended casters 38a come into contact with the original floor surface. At the same time, the support parts 439a are set into the aforementioned displacement state that they are released from the floor surface (i.e. the floor surface including the portions 6 in which the cones 407 are placed). When the buffer apparatus 430 positioned with respect to the manufacturing apparatus 20 is fixed, the jack bolts 38b are tightened clockwise, and the contracted casters 38a are released from the original floor surface. At the same time, the support parts 439a are set into the aforementioned fixed state that they engage with the cones 407. By this, the buffer apparatus 430 is disposed more stably than the case of the simple flat floor surface, as in the case of FIG. 13, while avoiding the danger to a person caused by the placement of the cones 407.

<Method of Travelling Transfer Apparatus>

FIG. 15A is a top view showing a buffer apparatus 530 positioned with respect to the load port LP1, and FIG. 15B is a side view showing the buffer apparatus 530 in FIG. 15A. Incidentally, in FIG. 15, the same constituent elements as in the case of the buffer apparatus 30 in FIG. 9 described above will carry the same referential numerals, and the explanation thereof will be omitted.

In FIG. 15, the buffer apparatus 530 is not provided with a travelling device, such as the travel roller 38 in FIG. 9, and the buffer apparatus 530 cannot be displaced by itself. Thus, for the displacement of the buffer apparatus 530, a jack carriage 50 (i.e. one example of the “travelling device” of the present invention) is used. The jack carriage 50 is provided with a not-illustrated hydraulic jack part; a support table 51, which can support the bottom surface of the main body of the buffer apparatus 530; a plurality of roller parts 52, which have wheels and which are displaceably mounted on the bottom surface of the support table 51; a handhold 53, which is held by the system administrator when the jack carriage 50 is displaced (i.e. including when the buffer apparatus 530 is displaced). When the buffer apparatus 530 supported by the plurality of legs 39 is displaced after being positioned with respect to the manufacturing apparatus 20, firstly, the roller parts 52 are inclined (i.e. shown by the roller parts in dashed lines in FIG. 15B) by the power of the jack part, thereby setting the support table 51 at a level (i.e. entrance level) which allows the support table 51 to enter below the main body of the buffer apparatus 530. Then, the jack carriage 50 is displaced in the X direction by the operation of handhold 53, and the support table 51 at the entrance level is disposed below the center of the main body of the buffer apparatus 530 away from the plurality of legs 39. Then, by the operation of the jack part, the inclined roller parts 52 are made vertical (i.e. shown by the roller parts in solid lines in FIG. 15B). Then, the plurality of legs 39 are released from the floor surface, and the support table 51 is set at a level (i.e. support level) which allows the support table 51 to be in contact with the bottom surface of the main body of the buffer apparatus 530, so that the buffer apparatus 530 is set into the displacement state. After that, if the jack carriage 50 is pulled in the X direction from a position at which an abutting part 33 abuts on the positioning block 5 and is released from a position at which the buffer apparatus 530 is positioned with respect to the manufacturing apparatus 20 by the operation of the handhold 53, the buffer apparatus 530 can be arbitrarily displaced. The displacement here may be performed by man power, or by using an external or built-in power mechanism, such as an electric motor. Incidentally, if the buffer apparatus 530 in displacement is positioned with respect to the manufacturing apparatus 20, the aforementioned processes may be performed in the reverse order.

<Method of Fixing Upper Part of Transfer Apparatus>

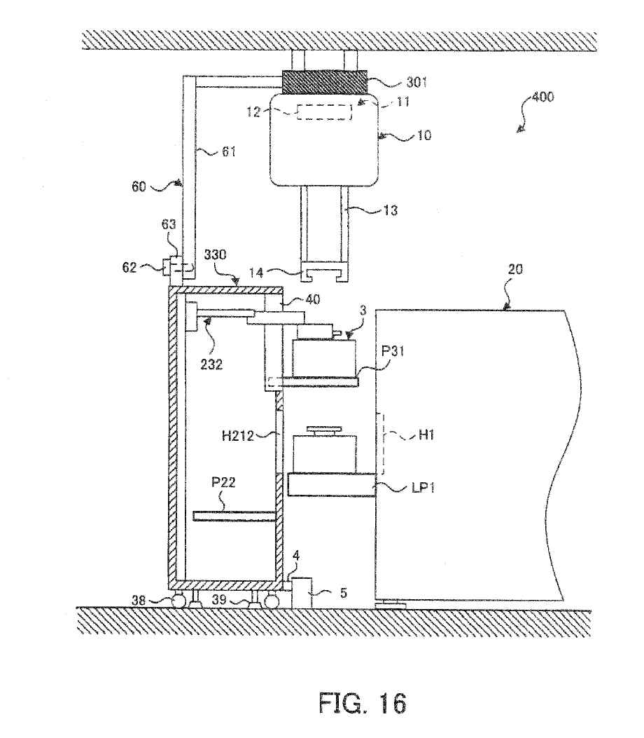

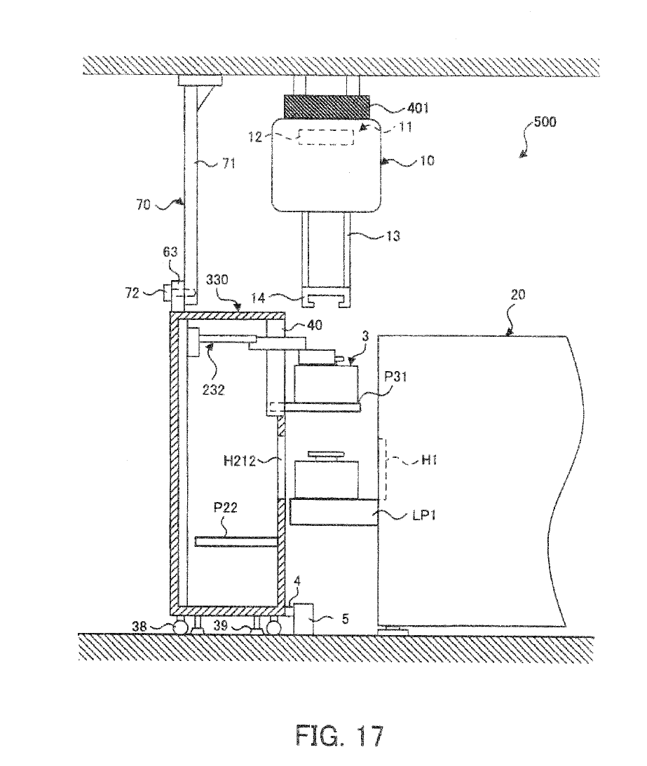

Next, with reference to FIG. 16 and FIG. 17, a method of fixing the transfer apparatus in the first embodiment will be explained. FIG. 16 is a one-direction cross sectional view showing one example of the fixing device for fixing the transfer apparatus in the embodiment. FIG. 17 is a one-direction cross sectional view for explaining one example of the fixing device in another form which is different from the fixing device in FIG. 16. Incidentally, in FIG. 16 and FIG. 17, the same constituent elements as in the case of the buffer apparatus 230 in FIG. 8 described above will carry the same referential numerals, and the explanation thereof will be omitted.

In FIG. 16, the buffer apparatus 330 is provided with a fixation part 63 for fixing the upper part of the main body of the buffer apparatus 530. The fixation part 63 has an opening which can let through a connection bolt 62 described later. In contrast, a bracket 60 (i.e. one example of the “fixing device” of the present invention) which can be connected to the fixation part 63 is fixed to a rail 301. The bracket 60 is provided with a main body part 61 and the connection bolt 62. One end of the main body part 61 is fixed on the side surface of the rail 301, and the other end has an opening which can screw in the connection bolt 62. If the buffer apparatus 330 is positioned with respect to the manufacturing apparatus 20, the other end abuts on the fixation part 63 on the buffer apparatus 330 side. In this condition, the fixation part 63 is screwed to the main body part 61 by using the connection bolt 62, by which the upper part of the buffer apparatus 330 is fixed and the buffer apparatus 30 is more stably disposed.

In FIG. 17, a bracket 70 (one example of the “fixing device” of the present invention) is fixed on the ceiling, with respect to the fixation part 63 of the buffer apparatus 330 which is also shown in FIG. 16. The bracket 70 is provided with a main body part 71 and a connection bolt 72, as in the bracket 60 in FIG. 16. When the buffer apparatus 330 is positioned with respect to the manufacturing apparatus 20, the fixation part 63 is screwed to the main body part 71 by using the connection bolt 72 while the other end of the main body part 71 abuts on the fixation part 63 on the buffer apparatus 330 side, by which the upper part of the buffer apparatus 330 is fixed and the buffer apparatus 30 is more stably disposed.

<Method of Fixing Lower Part of Transfer Apparatus>

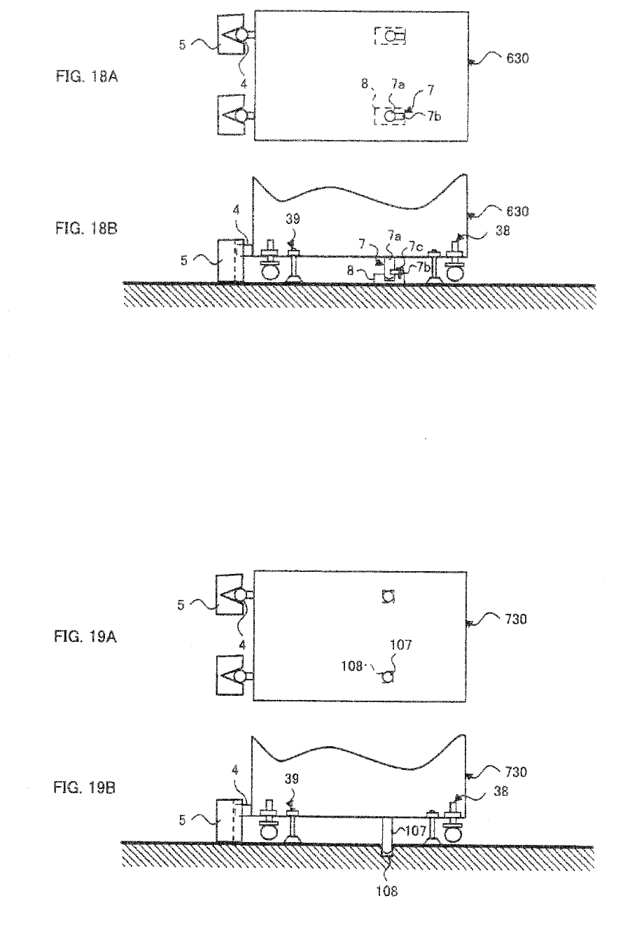

FIG. 18A is a top view showing a buffer apparatus 630 positioned with respect to the load port LP1, and FIG. 18B is a side view showing the buffer apparatus 630 in FIG. 18A. Incidentally, in FIG. 18, the same constituent elements as in the case of the buffer apparatus 30 in FIG. 9 described above will carry the same referential numerals, and the explanation thereof will be omitted.

In FIG. 18, a fixation pin 7 (one example of the “fixing device” of the present invention) for fixing the lower part of the main body of the buffer apparatus 630 is fixed on the bottom surface of the buffer apparatus 630. The fixation pin 7 is provided with a main body part 7a, a horizontal positioning part 7b, and a fixation bolt 7c. The main body part 7a has a concave portion on the side surface, and it can extend and contract in the perpendicular direction. One end of the horizontal positioning part 7b can engage with the concave portion of the main body part 7a in the horizontal one direction, and the other end has an opening which can let through the fixation bolt 7c. In contrast, a fixation part 8 is placed on the floor surface corresponding to the aforementioned fixation pin 7 of the buffer apparatus 630 positioned with respect to the manufacturing apparatus 20. The fixation part 8 has a concave portion which can engage with the fixation pin 7 and an opening which can screw in the fixation bolt 7c, on the upper surface. When the buffer apparatus 630 positioned with respect to the manufacturing apparatus 20 is fixed, the main body part 7a abuts on the concave portion of the fixation part 8, and one end of the horizontal positioning part 7b engages with the concave portion of the main body part 7a in the horizontal one direction. In this condition, the horizontal positioning part 7b is screwed to the fixation part 8 by using the fixation bolt 7c, by which the lower part of the buffer apparatus 630 is fixed on a predetermined horizontal surface and the buffer apparatus 30 is disposed more stably than the case where the legs 39 are simply in contact with the floor surface.

FIG. 19A is a top view showing a buffer apparatus 730 positioned with respect to the load port LP1, and FIG. 19B is a side view showing the buffer apparatus 730 in FIG. 19A. Incidentally, in FIG. 19, the same constituent elements as in the case of the buffer apparatus 30 in FIG. 9 described above will carry the same referential numerals, and the explanation thereof will be omitted.

In FIG. 19, a fixation pin 107 (one example of the “fixing device” of the present invention) for fixing the lower part of the main body of the buffer apparatus 730 is fixed on the bottom surface of the buffer apparatus 730. The main body of the fixation pin 107 can extend and contract in the perpendicular direction, partially as in the fixation pin 7 in FIG. 18. A portion 108 on the floor surface corresponding to the fixation pin 107 of the buffer apparatus 730 positioned with respect to the manufacturing apparatus 20 is lower than the original floor surface on which the manufacturing apparatus 20, the buffer apparatus 730, and the like are placed so that it can engage with the fixation pin 107. When the buffer apparatus 730 positioned with respect to the manufacturing apparatus 20 is fixed, the fixation pin 107 is extended and engages with the portion 108 of the floor surface. By this, the lower part of the buffer apparatus 730 is fixed in the horizontal direction and the buffer apparatus 30 is disposed more stably than the case where the legs 39 are simply in contact with the floor surface.

Incidentally, the positioning device, the fixing device, and the travelling device shown in FIG. 9 to FIG. 19 described above may be provided alone for the transfer apparatus of the present invention. Alternatively, one or a plurality of combinations of the plurality of devices may be provided.

The invention may be embodied in other specific forms without departing from the spirit or essential characteristics thereof. The present embodiments are therefore to be regarded in all respects as illustrative and not restrictive, the scope of the invention being indicated by the appended claims rather than by the foregoing or following description and all changes which come within the meaning and range of equivalency of the claims are therefore intended to be embraced therein. For example, a transfer apparatus provided with two second shelves for two ports (i.e. in which two transfer apparatuses in the embodiment are arranged side by side) is also included in the technical scope of the invention.

### Second Embodiment

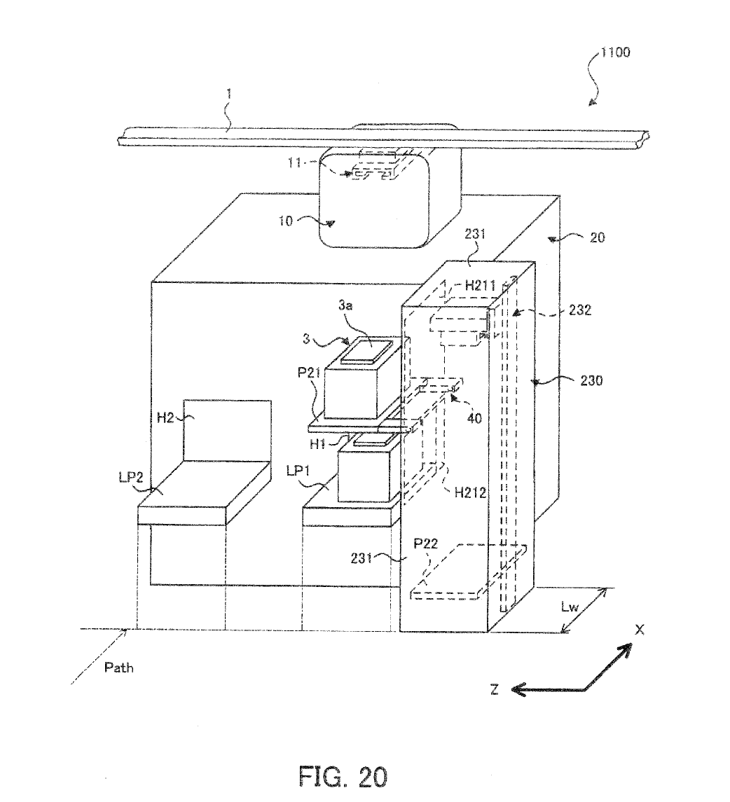

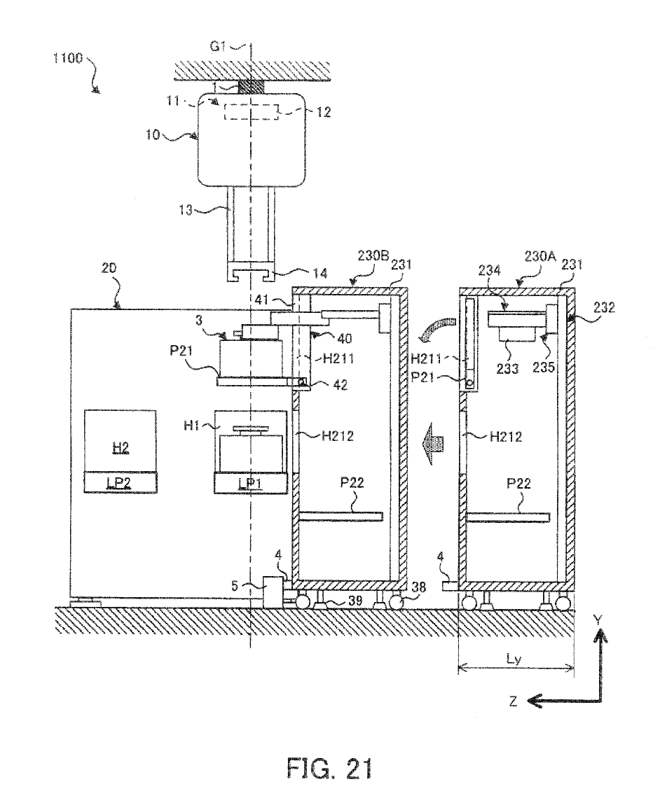

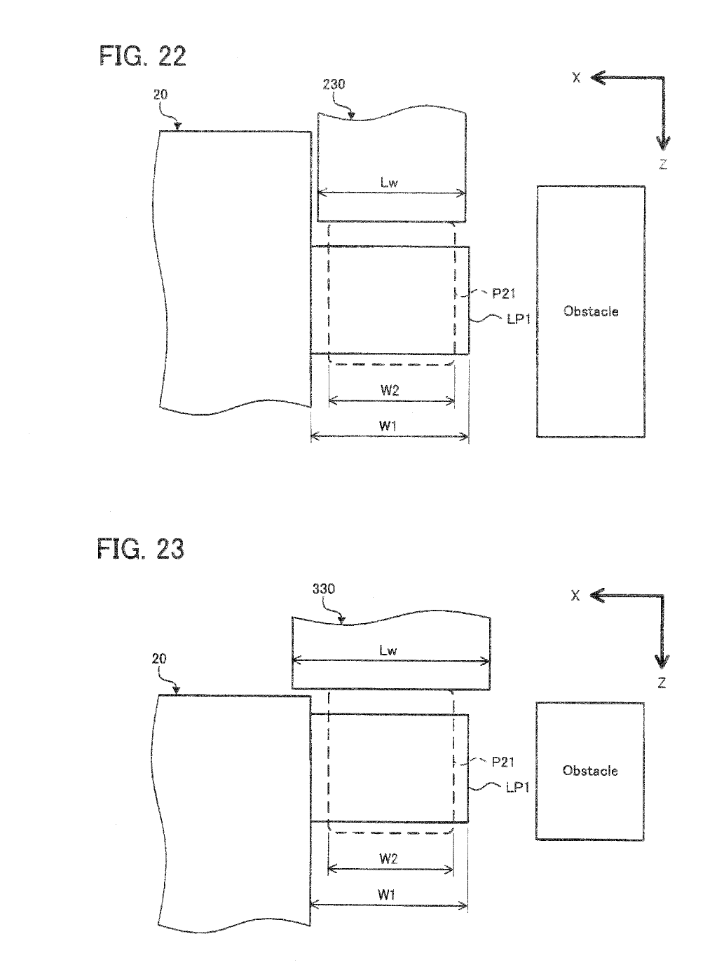

Next, the structure of a manufacturing system provided with a transfer apparatus in a second embodiment will be explained with reference to FIG. 20 to FIG. 22. FIG. 20 is a perspective view schematically showing the appearance of a manufacturing system provided with the transfer apparatus in FIG. 8, as a second embodiment. FIG. 21 is an another-direction cross sectional view conceptually showing a cross section when the transfer apparatus shown in FIG. 20 is cut in another direction (i.e. vertical direction in FIG. 20). FIG. 22 is a top view showing the arrangement of the transfer apparatus shown in FIG. 20 with respect to a processing apparatus. Incidentally, in FIG. 20 and FIG. 22, the same constituent elements as in the case of the manufacturing system 300 in FIG. 8 described above will carry the same referential numerals, and the explanation thereof will be omitted. The specification which is different from the case of the manufacturing system 300 in FIG. 8 will be particularly explained.

In FIG. 20, a manufacturing system 1100 is different from the manufacturing system 300 in FIG. 8 in that the buffer apparatus 230 is disposed on the side surface side (the right side in FIG. 20) of the load port LP1 instead of being disposed on the front side of the load port LP1. In other words, the manufacturing system 300 and the manufacturing system 1100 have different attachment positions of the buffer apparatus 230 to the load port LP1.

In the second embodiment, in particular, in FIG. 22, the buffer apparatus 230 is constructed such that a length W2 in the X direction of the load port P21 (i.e. in the direction perpendicular to the orientation of the rail 1) is less than or equal to a length W1 in the X direction of the load port LP1. Thus, for example, if there is an obstacle on the front side of the load port P21 (i.e. in the X direction in FIG. 21 and FIG. 22), the buffer apparatus 230 can approach the manufacturing apparatus 20 from the orientation of the rail 1 (i.e. the right side in a Z direction in FIG. 20 and FIG. 21). Moreover, the buffer apparatus 230 can transfer the FOUP3 from a position which is away on the right side in the Z direction of the load port LP1. Incidentally, the buffer apparatus 230 may be constructed such that the length W2 of the load port P21 is greater than or equal to the length W1 of the load port LP1. In this case, for example, the side part of the buffer apparatus 230 protrude into the path in FIG. 7; however, the protraction into the path can be significantly reduced, in comparison with the case where the buffer apparatus 230 is disposed on the front side of the load port LP21.

In the second embodiment, preferably, in the buffer apparatus 230, the width length Lw of the main body part 231 is less than or equal to the length W1 in the X direction of the load port LP1, and for example, the buffer apparatus 230 can be disposed in a space which is made on the side of the load port LP1 between the main body of the manufacturing apparatus 20 and the path without protruding into the path in FIG. 7. In FIG. 21, when the buffer apparatus 230 is attached to the load port LP1, it is displaced in the Z direction in the state that the OHT port P21 is accommodated at the accommodation position (i.e. the state of a buffer mechanism 230A in FIG. 21), and it is disposed on the side surface side of the load port LP1 which is the attachment target (i.e. the right side surface side of the load port LP1 in FIG. 21). Then, the buffer apparatus 230 is attached to the load port LP1 in the state that the OHT port P21 is displaced to the transfer position (i.e. the state of a buffer mechanism 230B in FIG. 21). At this time, the transfer mechanism 232 of the buffer apparatus 230 is disposed such that the longitudinal direction of a slide device 234 which can slide a holding device 233 matches the Z direction.

When the buffer mechanism 230 is in the state of the buffer mechanism 230B, for example, the holding device 233 is displaced in the Z direction toward to the load port LP1 by the horizontal displacement mechanism 234, and a pair of planar portions of the holding device 233 enters below the flange 3a of the FOUP3 on the load port LP1 and support the both ends of the flange 3a from below (i.e. hold the FOUP3). In other words, in the second embodiment, the transfer mechanism 232 can displace the holding device 233 by the mutual operation of the horizontal displacement mechanism 234 and a hoist mechanism 235 described above, in the Z direction (i.e. one example of the “third direction” of the present invention) and the vertical direction (one example of the “second direction” of the present invention) among the load port LP1, the OHT port P21, and the buffer P22.

According to the second embodiment, in the buffer apparatus 230, the orientation of the rail 1 matches the Z direction (i.e. the third direction) in which the horizontal displacement mechanism 234 displaces the FOUP3, so that the buffer apparatus 230 can be also disposed on the side of the load port LP1 (right beside in the second embodiment). As described above, if the buffer apparatus 230 is disposed on the side of the load port LP1, it is possible to effectively use the space which is made on the side of the load port LP1. On the other hand, the buffer apparatus 230 does not occupy the path at all, which is provided on the front side of the load port LP1 in the manufacturing apparatus 20, and the buffer apparatus 230 does not block a passage on the path at all. In other words, it is also possible to provide a narrow path in accordance with the arrangement of the buffer apparatus 230.

On the other hand, as described above, it is useful if the width length Lw of the main body part 231 is set to less than or equal to the length W1 in the X direction of the load port LP1; however, as shown in FIG. 23, it is also possible to set the width length Lw to greater than or equal to the length W1 in the X direction of the load port LP1. In this case, in FIG. 23, if the buffer apparatus 330 is brought close to the manufacturing apparatus 20 in the Z direction, the main body part of the buffer apparatus 330 collides with the outer frame of the manufacturing apparatus 20 or the corner of the main body of the manufacturing apparatus 20. In this case, however, it is not particularly problematic if the arrangement and size of the ports P21 and LP1 are constructed such that the OHT port P21 is located above the load port LP1 when or immediately before the buffer apparatus 330 collides with the corner of the main body of the manufacturing apparatus 20. For example, it is useful if the load port LP1 is provided as close to one corner on the front surface of the main body of the manufacturing apparatus 20 as possible (i.e. the right corner on the front surface of the manufacturing apparatus 20 in FIG. 20 and FIG. 21). Alternatively, in this case, the OHT port LP21 and the transfer mechanism 232 may be able to extend in the horizontal direction (i.e. toward the left side in FIG. 20 and FIG. 21). Moreover, by making the OHT port LP21 and the transfer mechanism 232 extendable, the buffer apparatus 330 can transfer the FOUP3 with respect to the load port LP2 located far away from the front surface of the manufacturing apparatus 20 (i.e. the load port on the left side in FIG. 20 and FIG. 21).

In the manufacturing system 1100 provided with the buffer apparatus 230 in the second embodiment, it is possible to perform the same process as the first transfer operation process in FIG. 4 or the second transfer operation process in FIG. 5 by using a controller in the manufacturing system 1100, with respect to the transfer operation between the vehicle 10 and the manufacturing apparatus 20 through the buffer apparatus 230 disposed on the side of the load port LP1, and it is also possible to quickly transfer the FOUP3 with respect to the load port LP1, thereby improving the operating rate of the manufacturing apparatus 20. Moreover, the buffer apparatus 230 can apply the positioning device (or positioning method), the fixing device (or fixing method), and the travelling device (or traveling method) in FIG. 9 to FIG. 19, and the buffer apparatus 230 can be more stably disposed by the devices.

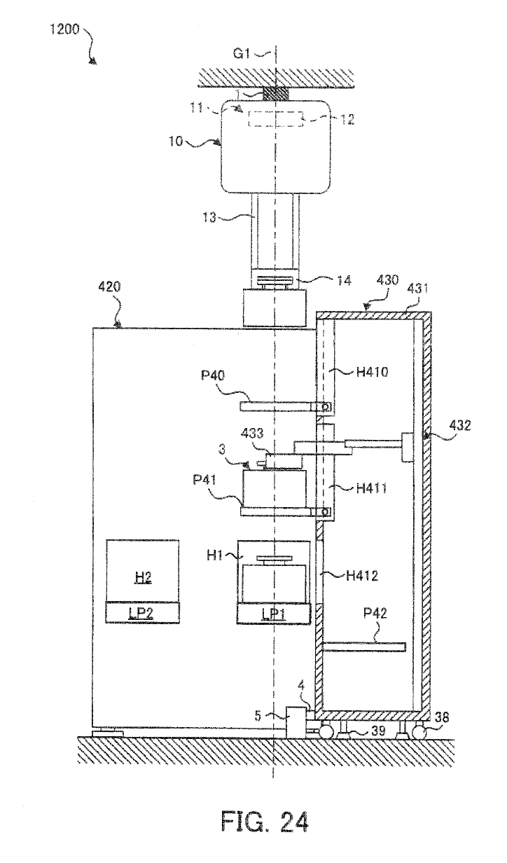

Incidentally, the buffer apparatus in the second embodiment described above may be also constructed such that its height is equal to or greater than the height of a manufacturing apparatus, in response to the large-scaled manufacturing apparatus. In this case, as shown in FIG. 24, the buffer apparatus 430 is constructed, for example, such that a second OHT port P40 can be disposed above an OHT port P41 corresponding to the OHT port P21 in FIG. 20. The second OHT port P40 is displaced between a transfer position at which the FOUP3 can be transferred with the vehicle 10 in the horizontal state and an accommodation position at which it is accommodated in a main body part 431 in the vertical state, as in the OHT port P41. For example, if the buffer apparatus 430 is disposed on the side surface side of the load port LP1 (i.e. the right side in FIG. 24), a transfer mechanism 432 is controlled by a controller in a manufacturing system 1200, and the transfer mechanism 432 displaces a holding device 433 in the Z direction (i.e. one example of the “third direction” of the present invention) and the vertical direction (one example of the “second direction” of the present invention) among the aforementioned second OHT port P40, the OHT port P41, and the transfer mechanism 432 holds or releases the FOUP3 on the holding device 433, thereby transferring the FOUP3 among them.

Incidentally, the buffer apparatus 430 can be disposed not only on the side surface side of the load port LP1 but also on the front side of the load port LP1, as in the buffer apparatus 30 in FIG. 2 as shown in FIG. 24. For example, the main body part 431 of the buffer apparatus 430 is provided with a frame which is free of as much side surfaces as possible. In this case, when it is to dispose the buffer apparatus 430 on the front side of the load port LP1, the buffer apparatus 430 can be attached to the load port LP1 such that one portion of the load port LP1 (i.e. the front part of the load port LP1) is located within the main body part 431. By this, it is possible to dispose the buffer apparatus 430 closer to the main body of a manufacturing apparatus 420 in the X direction, and for example, it is possible to reduce the protrusion of the buffer apparatus 430 into the path in FIG. 7.

The entire disclosure of Japanese Patent Application No. 2009-183310 filed on Aug. 6, 2009 including the specification, claims, drawings and summary is incorporated herein by reference in its entirety.

What is claimed is:

1. A transfer apparatus for transferring a transported object with a transporting vehicle, which travels along a track and which transports the transported object, and with a port which can take in and out the transported object or a processed object in a processing apparatus which performs a process on the processed object accommodated in the transported object, the transfer apparatus comprising:
a first shelf which is disposed to block an original transfer path in the middle which is from a transfer position at which the transporting vehicle transfers the transported object to the port and which can transfer the transported object with the transporting vehicle;
a second shelf which can at least temporarily put the transported object; and
a displacing device which can reciprocate the transported object with respect to the first shelf and the port in a first direction, which is a direction coming close to and going away from the processing apparatus, and which can reciprocate the transported object at a first direction position, which is away in the first direction at least by the transported object from the first shelf and the port, in a second direction crossing the first direction.

2. The transfer apparatus according to claim 1, wherein the second shelf is disposed at a position of the first direction position, which is not obstructive when the displacing device displaces the transported object in the first direction and the second direction between the first shelf and the port.

3. The transfer apparatus according to claim 1, wherein the second shelf is disposed between the first shelf and the port in the original transfer path.

4. The transfer apparatus according to claim 1, wherein
the processing apparatus has a plurality of ports, and
the transfer apparatus has a width which is less than or equal to an arrangement pitch of the ports in its outside dimension and is disposed such that the first direction matches a direction which is at right angles to a direction of arranging the ports.

5. The transfer apparatus according to claim 1, wherein the first shelf can be bent or accommodated on a main body side of the transfer apparatus.

6. The transfer apparatus according to claim 1, wherein
the transporting vehicle longitudinally transfers the transported object in a vertical direction,
the first direction is a horizontal one direction which is perpendicular to the vertical direction, and
the second direction is the vertical direction.

7. The transfer apparatus according to claim 1, wherein
the transfer apparatus has an outer shape which allows the transfer apparatus to be attached to the port, and
the transfer apparatus further comprises a positioning device for positioning the transfer apparatus with respect to the port.

8. The transfer apparatus according to claim 7, further comprising a fixing device which fixes the transfer apparatus in a state that the transfer apparatus is positioned by the positioning and which can release the fixation.

9. The transfer apparatus according to claim 1, further comprising a travelling device which enables the transfer apparatus to be displaced in the first direction.

10. The transfer apparatus according to claim 1, wherein
the displacing device has:
a holding device for holding the transported object;
a first displacing part capable of reciprocating the holding device in the first direction; and
a second displacing part capable of reciprocating the holding device in the second direction.

11. The transfer apparatus according to claim 1, further comprising a controlling device for controlling the displacing device, if one transported object transferred from the transporting vehicle to the first shelf is displaced to the port, firstly to displace the one transported object from the first shelf to the second shelf, secondly to displace another transported object, which is put on the port, from the port to the first shelf while the one transported object is temporarily put on the second shelf, and thirdly to displace the one transported object from the second shelf to the port.

12. The transfer apparatus according to claim 1, further comprising a controlling device for controlling the displacing device, if one transported object transferred from the transporting vehicle to the first shelf is displaced to the port, firstly to displace the one transported object to the port without temporarily putting the one transported object on the second shelf on which another transported object transferred to the second shelf is already put, and secondly to displace the other transported object from the second shelf to the first shelf.

13. A transfer apparatus for transferring a transported object with a transporting vehicle, which travels along a track and which transports the transported object, and with a port which can take in and out the transported object or a processed object in a processing apparatus which performs a process on the processed object accommodated in the transported object, the transfer apparatus comprising:
a first shelf which is disposed to block an original transfer path in the middle which is from a transfer position at which the transporting vehicle transfers the transported object to the port and which can transfer the transported object with the transporting vehicle;
a second shelf which can at least temporarily put the transported object; and
a displacing device which can reciprocate the transported object with respect to the first shelf and the port in a third direction, which is a direction along the processing apparatus and which is a direction coming close to and going away from the port, and which can reciprocate the transported object at a third direction position, which is away in the third direction at least by the transported object from the first shelf and the port, in a second direction crossing the third direction.

14. The transfer apparatus according to claim 13, wherein the transfer apparatus is disposed such that the third direction matches a direction along the track.
